(19) United States
(12) Patent Application Publication
(10) Pub. No.: US 2026/0120607 A1
(43) Pub. Date: Apr. 30, 2026

(54) DISPLAY PANEL, DISPLAY DEVICE, AND ELECTRONIC DEVICE

(71) Applicant: Samsung Display Co., Ltd., Yongin-si, Gyeonggi-do (KR)

(72) Inventors: JUNKI JEONG, Yongin-si (KR); HYUNJOON KIM, Yongin-si (KR); YOUNGWAN SEO, Yongin-si (KR); Jongyeop An, Yongin-si (KR)

(21) Appl. No.: 19/288,887

(22) Filed: Aug. 1, 2025

(30) Foreign Application Priority Data
Oct. 30, 2024 (KR) 10-2024-0151360

(51) Int. Cl. G09G 3/20; G09G 3/3233; H10K 59/131

(52) U.S. Cl. CPC G09G 3/2007; G09G 3/3233; H10K 59/131; G09G 2300/0426; G09G 2300/0819; G09G 2300/0852; G09G 2300/0861; G09G 2320/0223; G09G 2330/021

(57) ABSTRACT

A display panel includes a substrate including a first display area and a second display area, and a non-display area outside the first and second display areas, a first mesh line in the first display area, and electrically connected to pixels in the first display area, a second mesh line in the second display area, and electrically connected to pixels in the second display area, a first high power transmission line in the non-display area, electrically connected to the first mesh line, and configured to transmit a first high power voltage to the first mesh line, and a second high power transmission line in the non-display area, electrically connected to the second mesh line, and configured to transmit a second high power voltage to the second mesh line.

### CROSS-REFERENCE TO RELATED APPLICATION

The present application claims priority to, and the benefit of, Korean Patent Application No. 10-2024-0151360, filed on Oct. 30, 2024, in the Korean Intellectual Property Office, the entire disclosure of which is incorporated herein by reference.

### BACKGROUND

### 1. Field

Embodiments relate to a display panel, a display device, and an electronic device capable of reducing power consumption.

### 2. Description of the Related Art

In a display device, such as an organic light-emitting diode (“OLED”) display device, a power voltage (e.g., a high power voltage) provided to a display panel may be determined or set to be sufficiently high in consideration of a drain-source voltage of a driving transistor of each pixel, a voltage applied to an OLED and a voltage drop (e.g., an IR drop) margin of the power voltage. Further, when the display panel displays a low luminance image (or a low gray image), the power voltage may be set lower than the power voltage when the display panel displays a high luminance image (or a high gray image). Thus, the power consumption of the display device may be reduced when the display panel displays the low luminance image (or the low gray image).

However, in some display devices, the same power voltage may be applied to all pixels of the display panel. Accordingly, even if a low luminance image is displayed only in a portion of the display panel, the power voltage cannot be decreased, and thus the power consumption of the display device cannot be reduced.

### SUMMARY

Embodiments provide a display panel capable of reducing power consumption. Embodiments also provide a display device capable of reducing power consumption. Embodiments also provide an electronic device capable of reducing power consumption.

Additional aspects will be set forth in the description which follows, and in part will be apparent from the description, or may be learned by practice of the disclosed embodiments.

A display panel according to one or more embodiments includes a substrate including a first display area and a second display area, and a non-display area outside the first and second display areas, a first mesh line in the first display area, and electrically connected to pixels in the first display area, a second mesh line in the second display area, and electrically connected to pixels in the second display area, a first high power transmission line in the non-display area, electrically connected to the first mesh line, and configured to transmit a first high power voltage to the first mesh line, and a second high power transmission line in the non-display area, electrically connected to the second mesh line, and configured to transmit a second high power voltage to the second mesh line.

The first mesh line and the second mesh line may be electrically insulated from each other.

The first high power transmission line and the second high power transmission line may be electrically insulated from each other.

The first high power transmission line may extend in a first direction, wherein the second high power transmission line extends in the first direction, and is spaced apart from the first high power transmission line in a second direction crossing the first direction.

The display panel may further include first connection lines extending in the second direction, and connecting the first high power transmission line and the first mesh line, and second connection lines extending in the second direction, and connecting the second high power transmission line and the second mesh line.

The first display area may be in the second direction from the second high power transmission line, wherein the second display area is in the second direction from the first display area, and wherein a length of the second connection lines in the second direction is greater than a length of the first connection lines in the second direction.

The first connection lines may extend from the first high power transmission line in the second direction, may overlap the first display area in a plan view, and may be spaced apart from the second display area in the plan view, wherein the second connection lines extend from the second high power transmission line in the second direction, and overlap the first display area and the second display area in the plan view.

The second mesh line may include horizontal lines extending in the first direction, and spaced apart from each other in the second direction, and vertical lines extending in the second direction, spaced apart from each other in the first direction, at a different layer from the horizontal lines, and electrically connected to the horizontal lines through contact holes.

The second connection lines may be electrically connected to at least one of the horizontal lines in the second display area through a contact hole.

The second connection lines may be electrically connected to some of the horizontal lines in the second display area, which are in a central portion of the second display area in the second direction, through a contact hole.

The vertical lines, the first connection lines, and the second connection lines may be at a same layer.

One of the vertical lines in the second display area may be aligned with one of the first connection lines in the first display area in the second direction.

The second display area may be in the second direction from the first display area, wherein a virtual reference line extends in the second direction, and passes through a center of the first display area and a center of the second display area, and wherein the first connection lines includes first-first connection lines, and first-second connection lines symmetrical with the first-first connection lines with respect to the virtual reference line.

The second connection lines may include second-first connection lines adjacent to the first-first connection lines, and second-second connection lines symmetrical with the second-first connection lines with respect to the virtual reference line, and adjacent to the first-second connection lines.

The second display area may be in the second direction from the first display area, wherein a first virtual reference line extends in the second direction, and passes through the first display area and the second display area, wherein a second virtual reference line extends in the second direction, passes through the first display area and the second display area, and is spaced apart from the first virtual reference line in the first direction, wherein the first connection lines include a first-first connection line, a first-second connection line symmetrical with the first-first connection line with respect to the first virtual reference line, a first-third connection line adjacent to the first-second connection line, and a first-fourth connection line symmetrical with the first-third connection line with respect to the second virtual reference line.

The second connection lines may include a second-first connection line adjacent to the first-first connection line, a second-second connection line symmetrical with the second-first connection line with respect to the first virtual reference line, and adjacent to the first-second connection line, a second-third connection line adjacent to the first-third connection line, and a second-fourth connection line symmetrical with the second-third connection line with respect to the second virtual reference line, and adjacent to the first-fourth connection line.

A display device according to one or more embodiments includes a display panel including a first display area and a second display area, and a non-display area outside the first and second display areas, and a panel driver configured to drive the display panel based on input image data, and to provide high power voltages to the first and second display areas, respectively, wherein the display panel includes a first mesh line in the first display area, and electrically connected to pixels in the first display area, a second mesh line in the second display area, and electrically connected to pixels in the second display area, a first high power transmission line in the non-display area, electrically connected to the first mesh line, and configured to transmit a first high power voltage to the first mesh line, and a second high power transmission line in the non-display area, electrically connected to the second mesh line, and configured to transmit a second high power voltage to the second mesh line.

The panel driver may be configured to divide the input image data into region image data for the first and second display areas, wherein the panel driver is configured to determine a target voltage level of the high power voltages respectively corresponding the first and second display areas by analyzing a corresponding one of the region image data.

The panel driver may be configured to calculate an average gray level of gray levels represented by pixel data included in the corresponding one of the region image data, wherein the panel driver is configured to determine the target voltage level of a corresponding one of the high power voltages based on the average gray level.

An electronic device according to one or more embodiments includes a window, a housing coupled with the window to provide an internal space, a display panel accommodated in the internal space between the housing and the window, and including a first display area and a second display area, and a non-display area outside the first and second display areas, and a panel driver configured to drive the display panel based on input image data, and to provide high power voltages to the first and second display areas, respectively, wherein the display panel includes a first mesh line in the first display area, and electrically connected to pixels in the first display area, a second mesh line in the second display area, and electrically connected to pixels in the second display area, a first high power transmission line in the non-display area, electrically connected to the first mesh line, and configured to transmit a first high power voltage to the first mesh line, and a second high power transmission line in the non-display area, electrically connected to the second mesh line, and configured to transmit a second high power voltage to the second mesh line.

In a display device according to some embodiments, a plurality of high power voltages may be respectively provided to a plurality of display areas of a display panel, and a target voltage level of a high power voltage for each display area may be determined by analyzing region image data for the display area. Accordingly, power consumption of the display device may be relatively reduced.

It is to be understood that both the foregoing general description and the following detailed description are examples, and are intended to provide further explanation of the claimed embodiments.

### BRIEF DESCRIPTION OF THE DRAWINGS

The accompanying drawings, which are included to provide a further understanding of embodiments of the present disclosure, and are incorporated in and constitute a part of this specification, illustrate embodiments of the present disclosure, and together with the description serve to explain the embodiments.

FIG. 1 is a perspective view illustrating an electronic device according to one or more embodiments.

FIG. 2 is a block diagram illustrating a display device according to one or more embodiments.

FIG. 3 is a diagram illustrating an example of a display area of a display panel according to one or more embodiments.

FIG. 4 is a schematic diagram of an equivalent circuit of an example of a pixel included in a display panel according to one or more embodiments.

FIG. 5 is a plan view illustrating an example of a display panel according to one or more embodiments.

FIG. 6 is a cross-sectional view illustrating an example of a display panel according to one or more embodiments.

FIG. 7 is a plan view illustrating an example of horizontal transmission lines and vertical transmission lines included in a display panel according to one or more embodiments.

FIG. 8 is a plan view schematically illustrating an example of a portion of a display panel according to one or more embodiments.

FIG. 9 is an enlarged plan view of area A of FIG. 8.

FIG. 10 is a cross-sectional view taken along line I-I′ of FIG. 9.

FIG. 11 is a cross-sectional view taken along line II-II′ of FIG. 9.

FIG. 12 is a plan view schematically illustrating another example of a portion of a display panel according to one or more embodiments.

FIG. 13 is an enlarged plan view of area B of FIG. 12.

FIG. 14 is a cross-sectional view taken along line III-III′ of FIG. 13.

FIG. 15 is a cross-sectional view taken along line IV-IV′ of FIG. 13.

FIG. 16 is a plan view schematically illustrating still another example of a portion of a display panel according to one or more embodiments.

FIG. 17 is a plan view schematically illustrating still another example of a portion of a display panel according to one or more embodiments.

FIG. 18 is a block diagram illustrating an electronic device according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

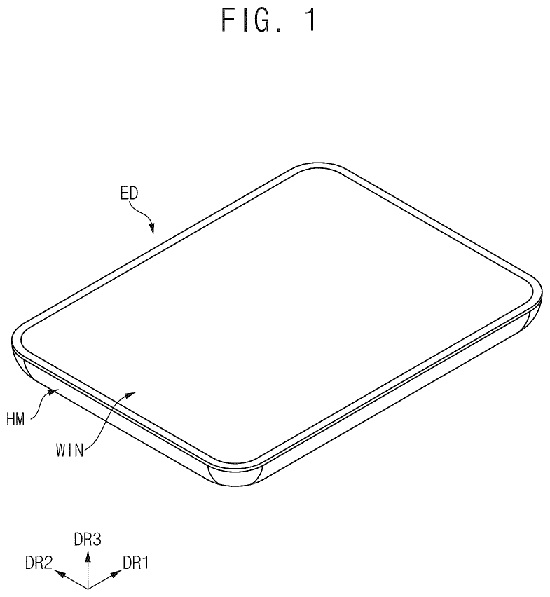

FIG. 1 is a perspective view illustrating an electronic device according to one or more embodiments.

In the specification, a plane may be defined by a first direction DR1, and by a second direction DR2 crossing the first direction DR1. For example, the first direction DR1 and the second direction DR2 may be substantially perpendicular to each other. An electronic device ED and various components or layers may have a thickness extending along a third direction DR3 crossing the plane. For example, the third direction DR3 may be substantially perpendicular to each of the first direction DR1 and the second direction DR2.

Referring to FIG. 1, an electronic device ED may be a device that is activated by an electrical signal, and may provide a display screen capable of displaying an image in the third direction DR3. For example, examples of the electronic device ED may include a tablet PC, a laptop, a television, a computer monitor, a vehicle monitor, a billboard, a smartphone, a mobile phone, a smart watch, a game console, a head-mounted display, or the like that provide the display screen.

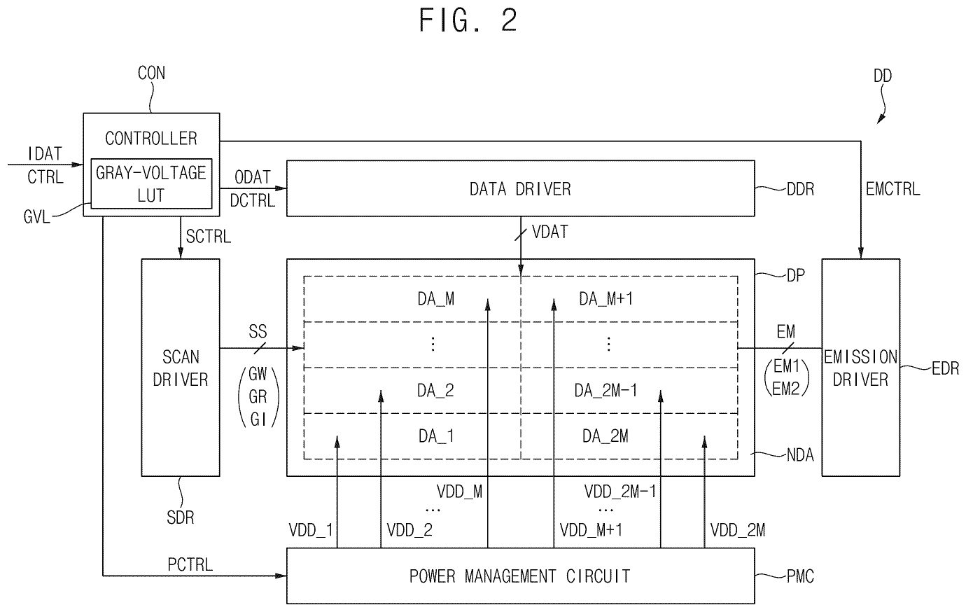

In one or more embodiments, the electronic device ED may include a window WU, a housing HM, and a display device (e.g., a display device DD of FIG. 2) for displaying an image. The window WU and the housing HM may be combined to define an external appearance of the electronic device ED.

The window WU may define a front surface (or an upper surface) of the electronic device ED. The window WU may have light-transmitting properties. For example, the window WU may include a resin film, such as polyimide, ultra-thin glass, or the like.

The housing HM may be combined with the window WU. The housing HM may be combined with the window WU to provide an internal space. The display device may be accommodated in the internal space provided between the housing HM and the window WU. Various components, such as an optical film, a cushion layer, a heating layer, a processor, a memory device, a storage device, a I/O device, a power supply, or the like, may be further accommodated in the internal space. The housing HM can include a material having relatively high rigidity. The housing HM can stably protect the components accommodated in the internal space from external impact.

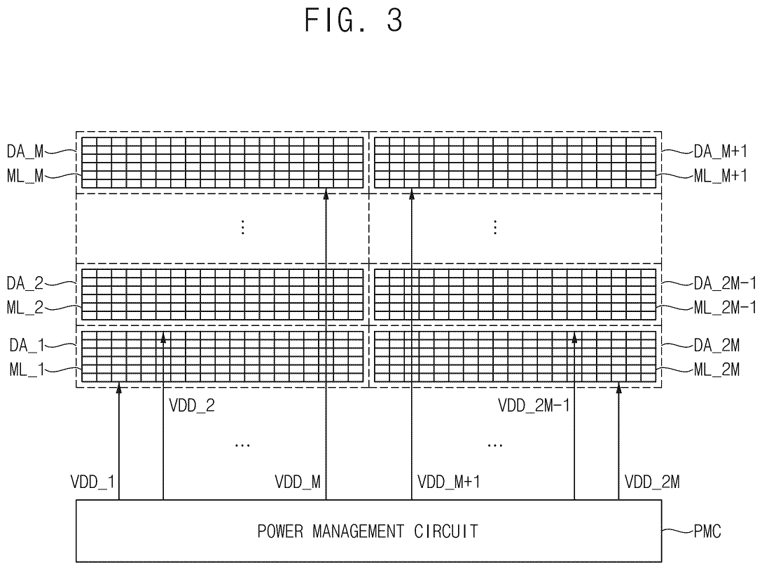

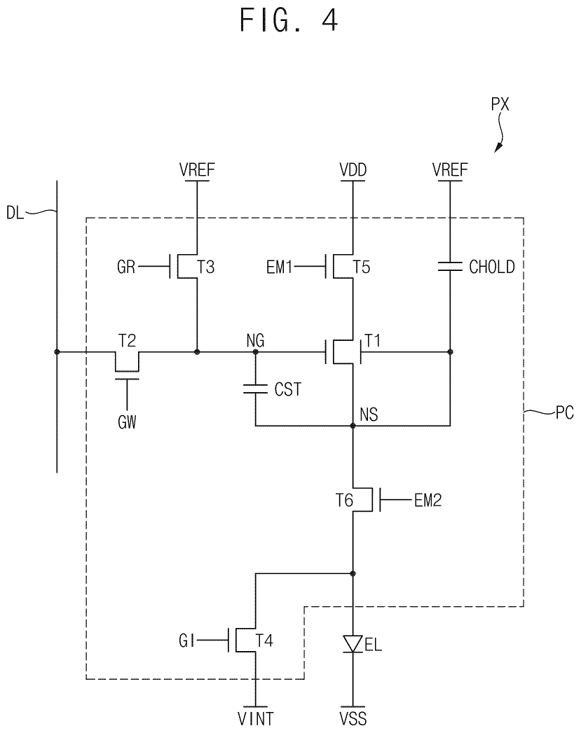

FIG. 2 is a block diagram illustrating a display device according to one or more embodiments. FIG. 3 is a diagram illustrating an example of a display area of a display panel according to one or more embodiments. FIG. 4 is a schematic diagram of an equivalent circuit of an example of a pixel included in a display panel according to one or more embodiments.

Hereinafter, the display device DD included in the electronic device ED of FIG. 1 will be described in more detail with reference to FIGS. 2 to 4.

Referring to FIGS. 2 to 4, the display device DD may include a display panel DP including a plurality of pixels PX, and a panel driver that drives the display panel DP based on input image data IDAT. In one or more embodiments, the panel driver may include a data driver DDR, a scan driver SDR, an emission driver EDR, a power management circuit PMC, and a controller CON. The data driver DDR may provide data voltages VDAT to the plurality of pixels PX. The scan driver SDR may provide scan signals SS to the plurality of pixels PX. The emission driver EDR may provide emission signals EM to the plurality of pixels PX. The power management circuit PMC may provide a plurality of high power voltages VDD_1 to VDD_2M to a plurality of display areas DA_1 to DA_2M of the display panel DP, respectively. The controller CON may control the data driver DDR, the scan driver SDR, the emission driver EDR, and the power management circuit PMC.

The display panel DP may include a plurality of data lines, a plurality of scan lines, a plurality of emission lines, and the plurality of pixels PX connected thereto. In addition, the display panel DP (or a substrate included in the display panel DP) may include the plurality of display areas DA_1 to DA_2M and a non-display area NDA.

The plurality of pixels PX may be arranged in each of the plurality of display areas DA_1 to DA_2M. The plurality of display areas DA_1 to DA_2M may receive the plurality of high power voltages VDD_1 to VDD_2M, respectively. For example, as illustrated in FIGS. 2 and 3, a left half of the display panel DP may include M display areas (first to (M)th display areas DA_1 to DA_M), where M is an integer greater than or equal to 2, and the right half of the display panel DP may include M display areas ((M+1)th to (2M)th display areas DA_M+1 to DA_2M), but the present disclosure is not limited thereto. The following description will focus on one or more embodiments in which the display panel DP includes the first to (2M)th display areas DA_1 to DA_2M.

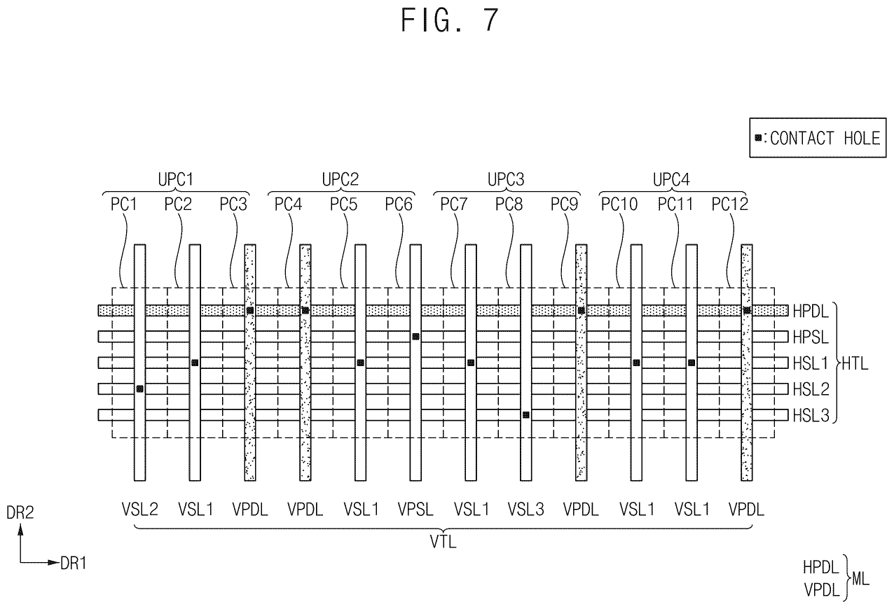

In one or more embodiments, as illustrated in FIG. 3, first to (2M)th mesh lines ML_1 to ML_2M may be arranged in the first to (2M)th display areas DA_1 to DA_2M, respectively. The first to (2M)th mesh lines ML_1 to ML_2M may be spaced apart from each other, and may be electrically insulated from each other. For example, each of the first to (2M)th mesh lines ML_1 to ML_2M may include a plurality of vertical lines each extending in a vertical direction (e.g., a pixel column direction or a direction in which the data line is extended), and a plurality of horizontal lines each extending in a horizontal direction (e.g., a pixel row direction or a direction in which the scan line is extended), and the plurality of vertical lines and the plurality of horizontal lines may be electrically connected to each other. Each of the first to (2M)th mesh lines ML_1 to ML_2M will be described in more detail later with reference to FIG. 7.

The first to (2M)th mesh lines ML_1 to ML_2M may receive first to (2M)th high power voltages VDD_1 to VDD_2M, respectively, from the power management circuit PMC. In addition, each of the first to (2M)th mesh lines ML_1 to ML_2M may be electrically connected to the plurality of pixels PX arranged in a corresponding display area, and may transmit the high power voltage received from the power management circuit PMC to the plurality of pixels PX. For example, the first mesh line ML_1 may provide the first high power voltage VDD_1 to the pixels PX arranged in the first display area DA_1, the second mesh line ML_2 may provide the second high power voltage VDD_2 to the pixels PX arranged in the second display area DA_2, the (M)th mesh line ML_M may provide the (M)th high power voltage VDD_M to the pixels PX arranged in the (M)th display area DA_M, the (M+1)th mesh line ML_M+1 may provide the (M+1)th high power voltage VDD_M+1 to the pixels PX arranged in the (M+1)th display area DA_M+1, the (2M−1)th mesh line ML_2M−1 may provide the (2M−1)th high power voltage VDD_2M−1 to the pixels PX arranged in the (2M−1)th display area DA_2M−1, and the (2M)th mesh line ML_2M may provide the (2M)th high power voltage VDD_2M to the pixels PX arranged in the (2M)th display area DA_2M.

The pixels PX may be arranged in each of the first to (2M)th display areas DA_1 to DA_2M of the display panel DP. For example, each of the pixels PX may emit one of red light, green light, and blue light, but the present disclosure is not limited thereto. As illustrated in FIG. 4, each of the pixels PX may include a pixel circuit PC and a light-emitting element EL. In one or more embodiments, the pixel circuit PC may include a first transistor T1, a second transistor T2, a third transistor T3, a fourth transistor T4, a fifth transistor T5, a sixth transistor T6, a first capacitor CST, and a second capacitor CHOLD.

The first transistor T1 may generate a driving current provided to the light-emitting element EL based on a voltage between a gate node NG and a source node NS, or a voltage stored between first and second electrodes of the first capacitor CST. In one or more embodiments, the first transistor T1 may include a gate connected to the gate node NG, a drain connected to the fifth transistor T5, and a source connected to the source node NS.

In one or more embodiments, the gate connected to the gate node NG may be a top gate located above an active layer of the first transistor T1, and the first transistor T1 may further include a bottom gate located under the active layer. That is, the first transistor T1 may have a double gate structure including the top gate and the bottom gate. In one or more embodiments, the bottom gate may be referred to as a bottom metal layer. The bottom gate of the first transistor T1 may be connected to the source node NS, a voltage of the bottom gate may be maintained or held by the second capacitor CHOLD, and thus a driving characteristic of the first transistor T1 may be relatively improved.

The second transistor T2 may transmit a data voltage to the gate node NG in response to a write signal GW. In one or more embodiments, the second transistor T2 may include a gate that receives the write signal GW, a first terminal connected to a data line DL, and a second terminal connected to the gate node NG.

The third transistor T3 may transmit a reference voltage VREF to the gate node NG in response to a reference signal GR. In one or more embodiments, the third transistor T3 may include a gate that receives the reference signal GR, a first terminal that receives the reference voltage VREF, and a second terminal connected to the gate node NG.

The fourth transistor T4 may transmit an initialization voltage VINT to an anode of the light-emitting element EL in response to an initialization signal GI. In one or more embodiments, the fourth transistor T4 may include a gate that receives the initialization signal GI, a first terminal connected to the anode of the light-emitting element EL, and a second terminal that receives the initialization voltage VINT.

The fifth transistor T5 may transmit a high power voltage VDD to the drain of the first transistor T1 in response to a first emission signal EM1. Here, the high power voltage VDD may be a corresponding one of the first to (2M)th high power voltages VDD_1 to VDD_2M received from the power management circuit PMC. For example, the high power voltage VDD may be the first high power voltage VDD_1 in a case where the pixel PX is arranged in the first display area DA_1. The high power voltage VDD may be the second high power voltage VDD_2 in a case where the pixel PX is arranged in the second display area DA_2. The high power voltage VDD may be the (M)th high power voltage VDD_M in a case where the pixel PX is arranged in the (M)th display area DA_M. The high power voltage VDD may be the (M+1)th high power voltage VDD_M+1 in a case where the pixel PX is arranged in the (M+1)th display area DA_M+1. The high power voltage VDD may be the (2M−1)th high power voltage VDD_2M−1 in a case where the pixel PX is arranged in the (2M−1)th display area DA_2M−1. The high power voltage VDD may be the (2M)th high power voltage VDD_2M in a case where the pixel PX is arranged in the (2M)th display area DA_2M. In one or more embodiments, the fifth transistor T5 may include a gate that receives the first emission signal EM1, a first terminal that receives the high power voltage VDD, and a second terminal connected to the drain of the first transistor T1.

The sixth transistor T6 may connect the source node NS to the anode of the light-emitting element EL in response to a second emission signal EM2. In one or more embodiments, the sixth transistor T6 may include a gate that receives the second emission signal EM2, a first terminal connected to the source node NS, and a second terminal connected to the anode of the light-emitting element EL.

The second capacitor CHOLD may be connected between a line which transmits the reference voltage VREF and the source node NS. In one or more embodiments, the second capacitor CHOLD may include a first electrode that receives the reference voltage VREF, and a second electrode connected to the source node NS.

The light-emitting element EL may emit light based on the driving current generated by the first transistor T1. In one or more embodiments, the light-emitting element EL may be an organic light-emitting diode (“OLED”), but the present disclosure is not limited thereto. In one or more other embodiments, the light-emitting element EL may be any suitable light-emitting element. For example, the light-emitting element EL may be a nano light-emitting diode (“NED”), a quantum dot (“QD”) light-emitting diode, a micro light-emitting diode, an inorganic light-emitting diode, or any other suitable light-emitting element. In one or more embodiments, the light-emitting element EL may include the anode connected to the fourth and sixth transistors T4 and T6, and a cathode that receives a low power voltage VSS.

In one or more embodiments, at least one of the first to sixth transistors T1 to T6 may be implemented as an N-type metal oxide semiconductor (“NMOS”) transistor, but the present disclosure is not limited thereto. For example, as illustrated in FIG. 3, all of the first to sixth transistors T1 to T6 may be implemented as NMOS transistors. In one or more other embodiments, some or all of the first to sixth transistors T1 to T6 may be implemented as a P-type metal oxide semiconductor (“PMOS”) transistors.

Although FIG. 4 illustrates an example in which the pixel circuit PC has a 6T2C structure, the pixel circuit PC of the pixel PX according to some embodiments is not limited to the example of FIG. 3, and may have any suitable structure.

Referring again to FIG. 2, the non-display area NDA may be located outside the first to (2M)th display areas DA_1 to DA_2M. For example, in a plan view, the non-display area NDA may surround the first to (2M)th display areas DA_1 to DA_2M. For example, the panel driver may be arranged on the non-display area NDA of the display panel DP.

The data driver DDR may generate the data voltages VDAT based on output image data ODAT and a data control signal DCTRL received from the controller CON, and may provide the data voltages VDAT to the plurality of pixels PX through the plurality of data lines. In one or more embodiments, the data control signal DCTRL may include an output data enable signal, a horizontal start signal, and a load signal, but the present disclosure is not limited thereto. In one or more embodiments, the data driver DDR and the controller CON may be implemented as a single integrated circuit, and the single integrated circuit may be referred to as a timing controller embedded data driver (“TED”) integrated circuit. In one or more other embodiments, the data driver DDR and the controller CON may be implemented as separate integrated circuits.

The scan driver SDR may generate the scan signals SS based on a scan control signal SCTRL received from the controller CON, and may sequentially provide the scan signals SS to the plurality of pixels PX through the plurality of scan lines on a row-by-row basis. In one or more embodiments, the scan control signal SCTRL may include a scan start signal, a scan clock signal, or the like, but the present disclosure is not limited thereto. Further, in one or more embodiments, the scan signals SS applied to each pixel PX may include the write signal GW, the reference signal GR, and the initialization signal GI illustrated in FIG. 4, but the present disclosure is not limited thereto. In one or more embodiments, the scan driver SDR may be integrated or formed in the display panel DP. In one or more other embodiments, the scan driver SDR may be implemented with one or more integrated circuits.

The emission driver EDR may generate the emission signals EM based on an emission control signal EMCTRL received from the controller CON, and may sequentially provide the emission signals EM to the plurality of pixels PX through the plurality of emission lines on a row-by-row basis. In one or more embodiments, the emission control signal EMCTRL may include an emission start signal, an emission clock signal, or the like, but the present disclosure is not limited thereto. Further, in one or more embodiments, the emission signals EM applied to each pixel PX may include the first and second emission signals EM1 and EM2 illustrated in FIG. 4, but the present disclosure is not limited thereto. In one or more embodiments, the emission driver EDR may be integrated or formed in the display panel DP. In one or more other embodiments, the emission driver EDR may be implemented with one or more integrated circuits.

The power management circuit PMC may generate voltages for an operation of the display device DD based on a power control signal PCTRL received from the controller CON. For example, the power management circuit PMC may generate the first to (2M)th high power voltages VDD_1 to VDD_2M, the low power voltage VSS, the reference voltage VREF, and the initialization voltage VINT provided to the display panel DP. Further, the power management circuit PMC may provide the first to (2M)th high power voltages VDD_1 to VDD_2M to the first to (2M)th mesh lines ML_1 to ML_2M of the first to (2M)th display areas DA_1 to DA_2M, respectively. In one or more embodiments, the power management circuit PMC may be implemented as a power management integrated circuit (“PMIC”), but the present disclosure is not limited thereto. In one or more other embodiments, the power management circuit PMC may be included in the controller CON and/or the data driver DDR.

The controller CON (e.g., a timing controller) may receive the input image data IDAT and a control signal CTRL from an external processor (e.g., a graphics processing unit (“GPU”), an application processor (“AP”), or a graphics card). In one or more embodiments, the control signal CTRL may include a vertical synchronization signal, a horizontal synchronization signal, an input data enable signal, a master clock signal, or the like, but the present disclosure is not limited thereto. The controller CON may generate the output image data ODAT, the data control signal DCTRL, the scan control signal SCTRL, the emission control signal EMCTRL, and the power control signal PCTRL based on the input image data IDAT and the control signal CTRL. The controller CON may control the data driver DDR by providing the output image data ODAT and the data control signal DCTRL to the data driver DDR, may control the scan driver SDR by providing the scan control signal SCTRL to the scan driver SDR, may control the emission driver EDR by providing the emission control signal EMCTRL to the emission driver EDR, and may control the power management circuit PMC by providing the power control signal PCTRL to the power management circuit PMC.

In the display device DD according to some embodiments, the controller CON may divide the input image data IDAT for the display panel DP into first to (2M)th region image data for the first to (2M)th display areas DA_1 to DA_2M, and may determine target voltage levels of the first to (2M)th high power voltages VDD_1 to VDD_2M for the first to (2M)th display areas DA_1 to DA_2M by analyzing the plurality of region image data for the first to (2M)th display areas DA_1 to DA_2M, respectively. In one or more embodiments, with respect to each display area, the controller CON may calculate an average gray level of a plurality of gray levels represented by a plurality of pixel data included in the region image data for the display area, and may determine the target voltage level of the high power voltage VDD for the display area based on the average gray level.

For example, the controller CON may determine a target voltage level of the first high power voltage VDD_1 for the first display area DA_1 based on an average gray level of a plurality of gray levels represented by a plurality of pixel data for the pixels PX included in the first display area DA_1. The controller CON may determine a target voltage level of the second high power voltage VDD_2 for the second display area DA_2 based on an average gray level of a plurality of gray levels represented by a plurality of pixel data for the pixels PX included in the second display area DA_2. The controller CON may determine a target voltage level of the (M)th high power voltage VDD_M for the (M)th display area DA_M based on an average gray level of a plurality of gray levels represented by a plurality of pixel data for the pixels PX included in the (M)th display area DA_M. The controller CON may determine a target voltage level of the (M+1)th high power voltage VDD_M+1 for the (M+1)th display area DA_M+1 based on an average gray level of a plurality of gray levels represented by a plurality of pixel data for the pixels PX included in the (M+1)th display area DA_M+1. The controller CON may determine a target voltage level of the (2M−1)th high power voltage VDD_2M−1 for the (2M−1)th display area DA_2M−1 based on an average gray level of a plurality of gray levels represented by a plurality of pixel data for the pixels PX included in the (2M−1)th display area DA_2M−1. The controller CON may determine a target voltage level of the (2M)th high power voltage VDD_2M for the (2M)th display area DA_2M based on an average gray level of a plurality of gray levels represented by a plurality of pixel data for the pixels PX included in the (2M)th display area DA_2M.

In one or more embodiments, to determine the target voltage level of the high power voltage VDD for each display area based on the average gray level for the display area, the controller CON may include a gray-voltage lookup table GVL. The gray-voltage lookup table GVL may store a plurality of voltage levels respectively corresponding to a plurality of gray ranges.

For example, the gray-voltage lookup table GVL may store a voltage level of about 9 V for a first gray range from a 255-gray level 255G to a 128-gray level 128G, a voltage level of about 8.5 V for a second gray range from a 127-gray level 127G to a 88-gray level 88G, a voltage level of about 8 V for a third gray range from a 87-gray level 87G to a 33-gray level 33G, and a voltage level of about 7.5 V for a fourth gray range from a 32-gray level 32G to a 0-gray level 0G.

Further, the controller CON may receive a voltage level corresponding to a gray range to which the average gray level belongs among the plurality of gray ranges from the gray-voltage lookup table GVL, and may determine the target voltage level of the corresponding high power voltage VDD as the voltage level received from the gray-voltage lookup table GVL.

For example, when the average gray level for the first display area DA_1 is a 200 gray-level within the first gray range, the target voltage level of the first high power voltage VDD_1 for the first display area DA_1 may be determined as about 9 V. When the average gray level for the second display area DA_2 is a 100 gray-level within the second gray range, the target voltage level of the second high power voltage VDD_2 for the second display area DA_2 may be determined as about 8.5 V. When the average gray level for the (M)th display area DA_M is a 60 gray-level within the third gray range, the target voltage level of the (M)th high power voltage VDD_M for the (M)th display area DA_M may be determined as about 8 V. When the average gray level for the (2M)th display area DA_2M is a 20 gray-level within the fourth gray range, the target voltage level of the (2M)th high power voltage VDD_2M for the (2M)th display area DA_2M may be determined as about 7.5 V. However, this is an example, and the present disclosure is not limited thereto.

As described above, the controller CON may determine the target voltage levels of the first to (2M)th high power voltages VDD_1 to VDD_2M for the first to (2M)th display areas DA_1 to DA_2M, and the power management circuit PMC may provide the first to (2M)th high power voltages VDD_1 to VDD_2M having the target voltage levels to the first to (2M)th display areas DA_1 to DA_2M, respectively. Accordingly, even if some display areas among the first to (2M)th display areas DA_1 to DA_2M display a high luminance image (or a high gray image), the high power voltages VDD of other display areas that display a low luminance image (or a low gray image) among the first to (2M)th display areas DA_1 to DA_2M may be decreased, and thus power consumption of the display device DD according to some embodiments may be relatively reduced.

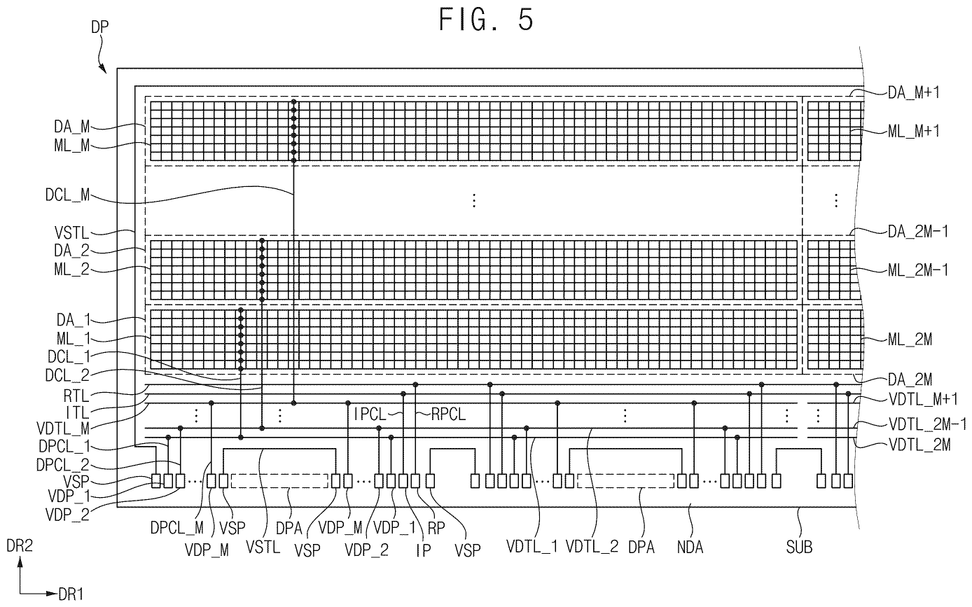

FIG. 5 is a plan view illustrating an example of a display panel according to one or more embodiments.

For example, FIG. 5 may focus on the left half of the display panel DP illustrated in FIG. 2.

Referring to FIGS. 2, 4, and 5, the display panel DP may include a plurality of pads and a plurality of transmission lines arranged in the non-display area NDA.

In one or more embodiments, the non-display area NDA may include a data pad area DPA in which a plurality of data pads spaced apart from each other are arranged. The data pads may respectively receive the data voltages VDAT from the data driver DDR. For example, as illustrated in FIG. 5, the non-display area NDA may include a plurality of data pad areas DPA spaced apart from each other in the first direction DR1. The plurality of data pads may be arranged in each of the data pad areas DPA.

In one or more embodiments, the display panel DP may include first to (M)th high power pads VDP_1 to VDP_M. The first to (M)th high power pads VDP_1 to VDP_M may be arranged on one side (e.g., a left side) of the non-display area NDA corresponding to the first to (M)th display areas DA_1 to DA_M. The first to (M)th high power pads VDP_1 to VDP_M may receive the first to (M)th high power voltages VDD_1 to VDD_M from the power management circuit PMC, respectively.

In one or more embodiments, as illustrated in FIG. 5, the first to (M)th high power pads VDP_1 to VDP_M may be arranged on both sides (e.g., both sides in the first direction DR1) of each data pad area DPA. For example, on the left side (e.g., a side of a direction opposite to the first direction DR1) of each data pad area DPA, the first to (M)th high power pads VDP_1 to VDP_M may be sequentially arranged in the first direction DR1, and on the right side (e.g., a side of the first direction DR1) of each data pad area DPA, the first to (M)th high power pads VDP_1 to VDP_M may be sequentially arranged in the direction opposite to the first direction DR1. That is, the first to (M)th high power pads VDP_1 to VDP_M may be symmetrically arranged with each other along the first direction DR1 with respect to each data pad area DPA, but the present disclosure is not limited thereto.

In addition, the display panel DP may further include (M+1)th to (2M)th high power pads arranged on the other side (e.g., a right side) of the non-display area NDA corresponding to the (M+1)th to (2M)th display areas DA_M+1 to DA_2M. The (M+1)th to (2M)th high power pads may receive the (M+1)th to (2M)th high power voltages VDD_M+1 to VDD_2M from the power management circuit PMC, respectively. An arrangement structure of the (M+1)th to (2M)th high power pads may be similar to the arrangement structure of the first to (M)th high power pads VDP_1 to VDP_M described above.

In one or more embodiments, the display panel DP may further include low power pads VSP, initialization voltage pads IP, and reference voltage pads RP. The low power pads VSP may receive the low power voltage VSS from the power management circuit PMC. For example, each low power pad VSP may be arranged between each data pad area DPA and the (M)th high power pad VDP_M adjacent the data pad area DPA, but the present disclosure is not limited thereto. The initialization voltage pads IP may receive the initialization voltage VINT from the power management circuit PMC. The reference voltage pads RP may receive the reference voltage VREF from the power management circuit PMC. For example, the low power pads VSP, the initialization voltage pads IP, and the reference voltage pads RP may be adjacent to, or among, the first to (M)th high power pads VDP_1 to VDP_M.

The display panel DP may include first to (2M)th high power transmission lines VDTL_1 to VDTL_2M arranged in the non-display area NDA. The first to (2M)th high power transmission lines VDTL_1 to VDTL_2M may be spaced apart from each other, and may be electrically insulated from each other. In one or more embodiments, each of the first to (2M)th high power transmission lines VDTL_1 to VDTL_2M may extend in the first direction DR1.

The first to (M)th high power transmission lines VDTL_1 to VDTL_M may be arranged on one side (e.g., the left side) of the non-display area NDA corresponding to the first to (M)th display areas DA_1 to DA_M. The first to (M)th high power transmission lines VDTL_1 to VDTL_M may be spaced apart from each other in the second direction DR2. For example, as illustrated in FIG. 5, the first to (M)th high power transmission lines VDTL_1 to VDTL_M may be sequentially arranged in the second direction DR2, but the present disclosure is not limited thereto.

The first to (M)th high power transmission lines VDTL_1 to VDTL_M may be electrically connected to the first to (M)th high power pads VDP_1 to VDP_M through first to (M)th high power pad connection lines DPCL_1 to DPCL_M, respectively. Accordingly, the first to (M)th high power transmission lines VDTL_1 to VDTL_M may receive the first to (M)th high power voltages VDD_1 to VDD_M from the power management circuit PMC, respectively. Each of the first to (M)th high power pad connection lines DPCL_1 to DPCL_M may extend in the second direction DR2.

The (M+1)th to (2M)th high power transmission lines VDTL_M+1 to VDTL_2M may be arranged on one side (e.g., the right side) of the non-display area NDA corresponding to the (M+1)th to (2M)th display areas DA_M+1 to DA_2M. The (M+1)th to (2M)th high power transmission lines VDTL_M+1 to VDTL_2M may be spaced apart from each other in the second direction DR2. For example, as illustrated in FIG. 5, the (M+1)th to (2M)th high power transmission lines VDTL_M+1 to VDTL_2M may be sequentially arranged in a direction opposite to the second direction DR2, but the present disclosure is not limited thereto.

The (M+1)th to (2M)th high power transmission lines VDTL_M+1 to VDTL_2M may be electrically connected to (M+1)th to (2M)th high power pads through (M+1)th to (2M)th high power pad connection lines, respectively. Accordingly, the (M+1)th to (2M)th high power transmission lines VDTL_M+1 to VDTL_2M may receive the (M+1)th to (2M)th high power voltages VDD_M+1 to VDD_2M from the power management circuit PMC, respectively. Each of the (M+1)th to (2M)th high power pad connection lines may extend in the second direction DR2.

The display panel DP may further include low power transmission lines VSTL, an initialization voltage transmission line ITL, and a reference voltage transmission line RTL arranged in the non-display area NDA.

In one or more embodiments, as illustrated in FIG. 5, one of the low power transmission lines VSTL may extend to surround the first to (2M)th display areas DA_1 to DA_2M. The remainder of the low power transmission lines VSTL may be arranged adjacent to the first high power transmission line VDTL_1 or the (2M)th high power transmission line VDTL_2M. However, the present disclosure is not limited thereto.

In one or more embodiments, the initialization voltage transmission line ITL may extend in the first direction DR1. The initialization voltage transmission line ITL may be spaced apart from the first to (2M)th high power transmission lines VDTL_1 to VDTL_2M in the second direction DR2. For example, the initialization voltage transmission line ITL may extend in the first direction DR1 in the non-display area NDA corresponding to the entirety of the first to (2M)th display areas DA_1 to DA_2M. That is, a length of the initialization voltage transmission line ITL in the first direction DR1 may be greater than a length of each of the first to (2M)th high power transmission lines VDTL_1 to VDTL_2M in the first direction DR1. For example, the length of the initialization voltage transmission line ITL in the first direction DR1 may be greater than a sum of a length of the first high power transmission line VDTL_1 in the first direction DR1 and a length of the (2M)th high power transmission line VDTL_2M in the first direction DR1.

The initialization voltage transmission line ITL may be electrically connected to the initialization voltage pads IP through initialization pad connection lines IPCL. Accordingly, the initialization voltage transmission line ITL may receive the initialization voltage VINT from the power management circuit PMC. Each of the initialization pad connection lines IPCL may extend in the second direction DR2.

In one or more embodiments, the reference voltage transmission line RTL may extend in the first direction DR1. The reference voltage transmission line RTL may be spaced apart from the first to (2M)th high power transmission lines VDTL_1 to VDTL_2M in the second direction DR2. The reference voltage transmission line RTL may be spaced apart from the initialization voltage transmission line ITL in the second direction DR2. For example, the reference voltage transmission line RTL may extend in the first direction DR1 in the non-display area NDA corresponding to an entirety of the first to (2M)th display areas DA_1 to DA_2M. That is, a length of the reference voltage transmission line RTL in the first direction DR1 may be greater than the length of each of the first to (2M)th high power transmission lines VDTL_1 to VDTL_2M in the first direction DR1. For example, the length of the reference voltage transmission line RTL in the first direction DR1 may be greater than the sum of the length of the first high power transmission line VDTL_1 in the first direction DR1 and the length of the (2M)th high power transmission line VDTL_2M in the first direction DR1.

The reference voltage transmission line RTL may be electrically connected to the reference voltage pads RP through reference pad connection lines RPCL. Accordingly, the reference voltage transmission line RTL may receive the reference voltage VREF from the power management circuit PMC. Each of the reference pad connection lines RPCL may extend in the second direction DR2.

In one or more embodiments, the display panel DP may further include first to (M)th connection lines DCL_1 to DCL_M that connect the first to (M)th high power transmission lines VDTL_1 to VDTL_M and the first to (M)th mesh lines ML_1 to ML_M, respectively. For example, each of the first to (M)th connection lines DCL_1 to DCL_M may extend in the second direction DR2.

The first connection line DCL_1 may electrically connect the first high power transmission line VDTL_1 in the non-display area NDA and the first mesh line ML_1 in the first display area DA_1. Although only one first connection line DCL_1 is illustrated in FIG. 5, as described below, a plurality of first connection lines DCL_1 spaced apart from each other in the first direction DR1 may electrically connect the first high power transmission line VDTL_1 and the first mesh line ML_1. Accordingly, the first high power voltage VDD_1 generated in the power management circuit PMC may be transmitted to the first mesh line ML_1 in the first display area DA_1 and the pixels PX in the first display area DA_1, which are connected to the first mesh line ML_1, through the first high power pad VDP_1, the first high power pad connection line DPCL_1, the first high power transmission line VDTL_1, and the first connection lines DCL_1.

In one or more embodiments, in a plan view, each of the first connection lines DCL_1 may overlap the first to (M)th high power transmission lines VDTL_1 to VDTL_M. Each of the first connection lines DCL_1 may be electrically connected to the first high power transmission line VDTL_1 through a contact hole, and may be electrically insulated from (e.g., might not be electrically connected to) the second to (M)th high power transmission lines VDTL_2 to VDTL_M.

In one or more embodiments, in a plan view, each of the first connection lines DCL_1 may overlap the first display area DA_1, and may not overlap the second to (M)th display areas DA_2 to DA_M. That is, in a plan view, each of the first connection lines DCL_1 may be spaced apart from the second to (M)th display areas DA_2 to DA_M. In other words, in a plan view, each of the first connection lines DCL_1 may overlap the first mesh line ML_1, and may not overlap the second to (M)th mesh lines ML_2 to ML_M. That is, in a plan view, each of the first connection lines DCL_1 may be spaced apart from the second to (M)th mesh lines ML_2 to ML_M. Each of the first connection lines DCL_1 may be electrically connected to the first mesh line ML_1 through at least one contact hole.

The second connection line DCL_2 may electrically connect the second high power transmission line VDTL_2 in the non-display area NDA and the second mesh line ML_2 in the second display area DA_2. Similarly, although only one second connection line DCL_2 is illustrated in FIG. 5, as described below, a plurality of second connection lines DCL_2 spaced apart from each other in the first direction DR1 may electrically connect the second high power transmission line VDTL_2 and the second mesh line ML_2. Accordingly, the second high power voltage VDD_2 generated in the power management circuit PMC may be transmitted to the second mesh line ML_2 in the second display area DA_2 and to the pixels PX in the second display area DA_2, which are connected to the second mesh line ML_2, through the second high power pad VDP_2, the second high power pad connection line DPCL_2, the second high power transmission line VDTL_2, and the second connection lines DCL_2.

In one or more embodiments, in a plan view, each of the second connection lines DCL_2 may not overlap the first high power transmission line VDTL_1, and may overlap the second to (M)th high power transmission lines VDTL_2 to VDTL_M. That is, in a plan view, each of the second connection lines DCL_2 may be spaced apart from the first high power transmission line VDTL_1. Each of the second connection lines DCL_2 may be electrically connected to the second high power transmission line VDTL_2 through a contact hole, and may be electrically insulated from (e.g., might not be electrically connected to) the (M)th high power transmission line VDTL_M.

In one or more embodiments, in a plan view, each of the second connection lines DCL_2 may overlap the first and second display areas DA_1 and DA_2, and may not overlap the (M)th display area DA_M. That is, in a plan view, each of the second connection lines DCL_2 may be spaced apart from the (M)th display area DA_M. In other words, in a plan view, each of the second connection lines DCL_2 may overlap the first and second mesh lines ML_1 and ML_2, and may not overlap the (M)th mesh line ML_M. That is, in a plan view, each of the second connection lines DCL_2 may be spaced apart from the (M)th mesh line ML_M. Each of the second connection lines DCL_2 may be electrically connected to the second mesh line ML_2 through at least one contact hole.

In one or more embodiments, a length of each of the second connection lines DCL_2 in the second direction DR2 may be greater than a length of each of the first connection lines DCL_1 in the second direction DR2.

The (M)th connection line DCL_M may electrically connect the (M)th high power transmission line VDTL_M in the non-display area NDA and the (M)th mesh line ML_M in the (M)th display area DA_M. Similarly, although only one (M)th connection line DCL_M is illustrated in FIG. 5, as described below, a plurality of (M)th connection lines DCL_M, which are spaced apart from each other in the first direction DR1, may electrically connect the (M)th high power transmission line VDTL_M and the (M)th mesh line ML_M. Accordingly, the (M)th high power voltage VDD_M generated in the power management circuit PMC may be transmitted to the (M)th mesh line ML_M in the (M)th display area DA_M and the pixels PX in the (M)th display area DA_M, which are connected to the (M)th mesh line ML_M, through the (M)th high power pad VDP_M, the (M)th high power pad connection line DPCL_M, the (M)th high power transmission line VDTL_M, and the (M)th connection lines DCL_M.

In one or more embodiments, in a plan view, each of the (M)th connection lines DCL_M may not overlap the first and second high power transmission lines VDTL_1 and VDTL_2, and may overlap the (M)th high power transmission line VDTL_M. That is, in a plan view, each of the (M)th connection lines DCL_M may be spaced apart from the first and second high power transmission lines VDTL_1 and VDTL_2. Each of the (M)th connection lines DCL_M may be electrically connected to the (M)th high power transmission line VDTL_M through a contact hole.

In one or more embodiments, in a plan view, each of the (M)th connection lines DCL_M may overlap the first to (M)th display areas DA_1 to DA_M. That is, in a plan view, each of the (M)th connection lines DCL_M may overlap the first to (M)th mesh lines ML_1 to ML_M. Each of the (M)th connection lines DCL_M may be electrically connected to the (M)th mesh line ML_M through at least one contact hole, and may be electrically insulated from (e.g., might not be electrically connected to) the first and second mesh lines ML_1 and ML_2.

In one or more embodiments, a length of each of the (M)th connection lines DCL_M in the second direction DR2 may be greater than the length of each of the first connection lines DCL_1 in the second direction DR2 and the length of each of the second connection lines DCL_2 in the second direction DR2.

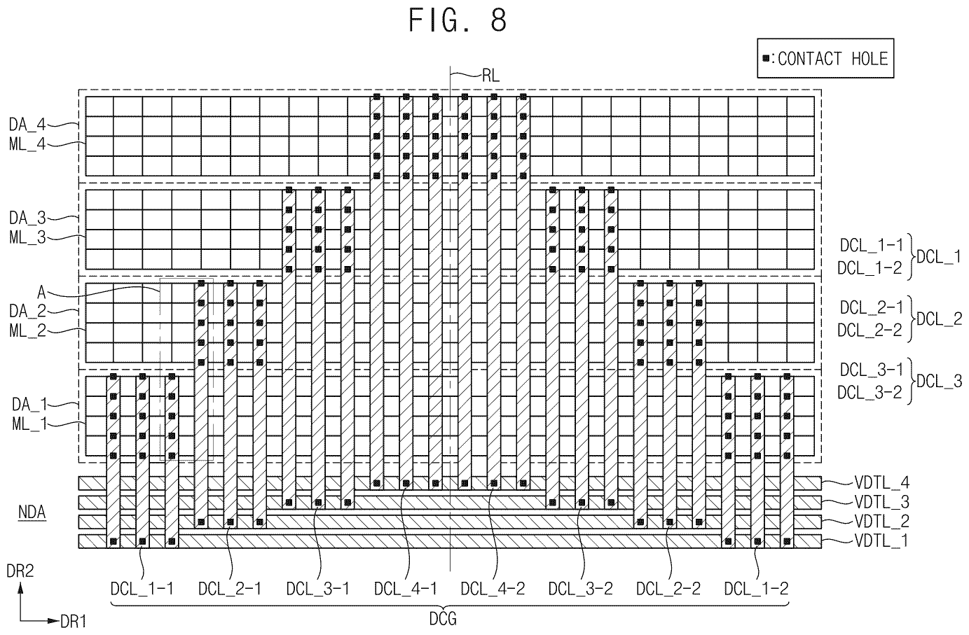

The connection relationship between the first to (M)th mesh lines ML_1 to ML_M and the first to (M)th connection lines DCL_1 to DCL_M will be described in more detail later with reference to FIGS. 8 to 11.

In addition, the display panel DP may further include (M+1)th to (2M)th connection lines for respectively connecting the (M+1)th to (2M)th high power transmission lines VDTL_M+1 to VDTL_2M and the (M+1)th to (2M)th mesh lines ML_M+1 to ML_2M. For example, each of the (M+1)th to (2M)th connection lines may extend in the second direction DR2. An arrangement structure of the (M+1)th to (2M)th connection lines may be similar to the arrangement structure of the first to (M)th connection lines DCL_1 to DCL_M described above.

In one or more embodiments, the display panel DP may further include initialization voltage connection lines connected to the initialization voltage transmission line ITL and reference voltage connection lines connected to the reference voltage transmission line RTL. Each of the initialization voltage connection lines and the reference voltage connection lines may extend in the second direction DR2. The initialization voltage connection lines may transmit the initialization voltage VINT to the pixels PX in the first to (2M)th display areas DA_1 to DA_2M. The reference voltage connection lines may transmit the reference voltage VREF to the pixels PX in the first to (2M)th display areas DA_1 to DA_2M.

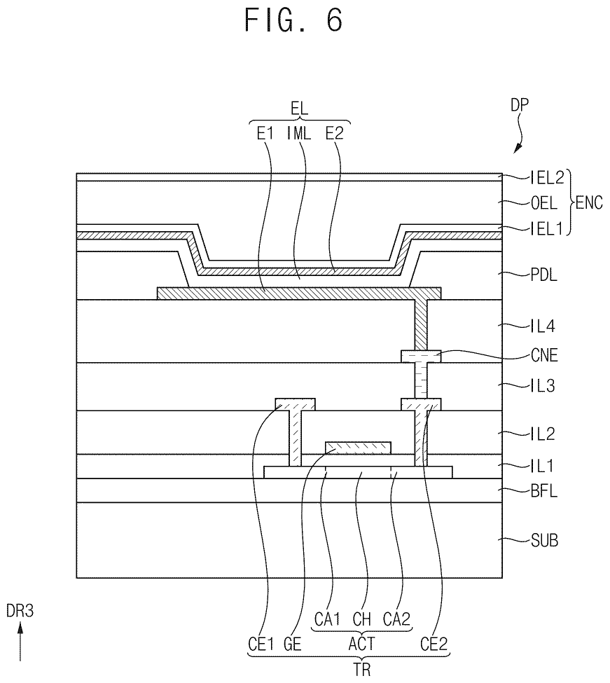

FIG. 6 is a cross-sectional view illustrating an example of a display panel according to one or more embodiments.

Hereinafter, a cross-sectional structure of the display panel DP will be described with reference to FIG. 6. For example, FIG. 6 may illustrate the pixel PX in one of the first to (2M)th display areas DA_1 to DA_2M of the display panel DP illustrated in FIG. 5.

Referring to FIG. 6, in one or more embodiments, the display panel DP may include a substrate SUB, a buffer layer BFL, a transistor TR, first to fourth insulating layers IL1, IL2, IL3, and IL4, a connection electrode CNE, a light-emitting element EL, a pixel-defining layer PDL, and an encapsulation layer ENC. The transistor TR may include an active layer ACT, a gate electrode GE, a first contact electrode CE1, and a second contact electrode CE2. For example, the transistor TR of FIG. 6 may be the sixth transistor T6 of FIG. 4. The light-emitting element EL may include a first electrode E1, an intermediate layer IML, and a second electrode E2.

The substrate SUB may form a base of the display panel DP. The substrate SUB may be an insulating substrate including or formed of a transparent or a non-transparent material.

The buffer layer BFL may be arranged on the substrate SUB. The buffer layer BFL may prevent or reduce impurities, such as oxygen or moisture, from penetrating into an upper portion of the substrate SUB through the substrate SUB. The buffer layer BFL may include an inorganic material, such as a silicon compound, a metal oxide, or the like. For example, the buffer layer BFL may include silicon oxide (SiOₓ), silicon nitride (SiNₓ), silicon oxynitride (SiOₓN_{y}), aluminum oxide (AlOₓ), aluminum nitride (AlNₓ), tantalum oxide (TaOₓ), hafnium oxide (HfOₓ), zirconium oxide (ZrOₓ), titanium oxide (TiOₓ), or the like. These may be used alone or in combination with each other. The buffer layer BFL may have a single layer structure or a multi-layer structure including a plurality of insulating layers.

The active layer ACT may be arranged on the buffer layer BFL. The active layer ACT may include an oxide semiconductor, a silicon semiconductor, an organic semiconductor, or the like. For example, the oxide semiconductor may include at least one selected from oxides of indium (In), gallium (Ga), tin (Sn), zirconium (Zr), vanadium (V), hafnium (Hf), cadmium (Cd), germanium (Ge), chromium (Cr), titanium (Ti), and zinc (Zn). The silicon semiconductor may include an amorphous silicon, a polycrystalline silicon, or the like. The active layer ACT may include a first contact area CA1, a second contact area CA2, and a channel area CH located between the first contact area CA1 and the second contact area CA2. Each of the first contact area CA1 and the second contact area CA2 may have higher conductivity than a conductivity of the channel area CH.

The first insulating layer IL1 may be arranged on the active layer ACT. The first insulating layer IL1 may cover the active layer ACT on the buffer layer BFL. The first insulating layer IL1 may include an inorganic insulating material.

The gate electrode GE may be arranged on the first insulating layer IL1. The gate electrode GE may overlap the channel area CH of the active layer ACT. The gate electrode GE may include a conductive material, such as a metal, an alloy, a conductive metal nitride, a conductive metal oxide, a transparent conductive material, or the like. For example, the gate electrode GE may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloys containing aluminum, alloys containing silver, alloys containing copper, alloys containing molybdenum, aluminum nitride (AlNₓ), tungsten nitride (WNₓ), titanium nitride (TiNₓ), chromium nitride (CrNₓ), tantalum nitride (TaNₓ), strontium ruthenium oxide (SrRuOₓ), zinc oxide (ZnOₓ), indium tin oxide (ITO), tin oxide (SnOₓ), indium oxide (InOₓ), gallium oxide (GaOₓ), indium zinc oxide (IZO), or the like. These may be used alone or in combination with each other. The gate electrode GE may have a single layer structure or a multi-layer structure including a plurality of conductive layers.

The second insulating layer IL2 may be arranged on the gate electrode GE. The second insulating layer IL2 may cover the gate electrode GE on the first insulating layer IL1. The second insulating layer IL2 may include an inorganic insulating material.

The first contact electrode CE1 and the second contact electrode CE2 may be arranged on the second insulating layer IL2. The first contact electrode CE1 and the second contact electrode CE2 may be connected to the first contact area CA1 and the second contact area CA2 of the active layer ACT, respectively. Each of the first contact electrode CE1 and the second contact electrode CE2 may include a conductive material.

The third insulating layer IL3 may be arranged on the first contact electrode CE1 and the second contact electrode CE2. The third insulating layer IL3 may include an inorganic insulating material and/or an organic insulating material.

The connection electrode CNE may be arranged on the third insulating layer IL3. The connection electrode CNE may include a conductive material. The connection electrode CNE may be connected to the second contact electrode CE2 through a contact hole penetrating the third insulating layer IL3.

The fourth insulating layer IL4 may be arranged on the connection electrode CNE. The fourth insulating layer IL4 may include an inorganic insulating material and/or an organic insulating material.

The first electrode E1 may be arranged on the fourth insulating layer IL4. The first electrode E1 may include a conductive material. The first electrode E1 may be connected to the connection electrode CNE through a contact hole penetrating the fourth insulating layer IL4. Accordingly, the first electrode E1 may be electrically connected to the transistor TR. For example, the first electrode E1 may be the anode of the light-emitting element LED.

The pixel-defining layer PDL may be arranged on the first electrode E1. The pixel-defining layer PDL may cover a peripheral portion of the first electrode E1, and may define a pixel opening exposing a central portion of the first electrode E1. The pixel opening may define an emission area. The pixel-defining layer PDL may include an organic insulating material. In one or more embodiments, the pixel-defining layer PDL may further include an inorganic material or an organic material including (or containing) a light-blocking material having a black color.

The intermediate layer IML may be arranged on the first electrode E1 and the pixel-defining layer PDL. A portion of the intermediate layer IML may be arranged in the pixel opening in the pixel-defining layer PDL. In one or more embodiments, the intermediate layer IML may include a first functional layer including an organic material, an emission layer arranged on the first functional layer and including an emission material, and a second functional layer arranged on the emission layer and including an organic material. For example, the first functional layer may include a hole injection layer, a hole transport layer, or the like, and the second functional layer may include an electron transport layer, an electron injection layer, or the like.

In one or more embodiments, the emission layer may include at least one of an organic light-emitting material or a quantum dot, but the present disclosure is not limited thereto.

In one or more embodiments, the organic light-emitting material may include a low molecular weight organic compound or a high molecular weight organic compound. Examples of the low molecular weight organic compound may include copper phthalocyanine, N, N′-diphenylbenzidine, tris-(8-hydroxyquinoline)aluminum, or the like. Examples of the high molecular weight organic compound may include poly(3,4-ethylenedioxythiophene), polyaniline, poly-phenylenevinylene, polyfluorene, or the like. These materials can be used alone or in a combination thereof.

In one or more embodiments, the quantum dot may include a core including a Group II-VI compound, a Group III-V compound, a Group IV-VI compound, a Group IV element, and/or a Group IV compound. In one or more embodiments, the quantum dot may have a core-shell structure including the core and a shell surrounding the core. The shell may act as a protection layer reducing or preventing the likelihood of the core being chemically denatured to maintain its semiconductor characteristics, and may act as a charging layer for imparting electrophoretic characteristics to the quantum dot.

The second electrode E2 may be arranged on the intermediate layer IML. The second electrode E2 may include a conductive material. For example, the second electrode E2 may be the cathode of the light-emitting element LED.

The encapsulation layer ENC may be arranged on the second electrode E2. The encapsulation layer ENC may include at least one inorganic encapsulation layer and at least one organic encapsulation layer. In one or more embodiments, the encapsulation layer ENC may include a first inorganic encapsulation layer IEL1 arranged on the second electrode E2, an organic encapsulation layer OEL arranged on the first inorganic encapsulation layer IEL1, and a second inorganic encapsulation layer IEL2 arranged on the organic encapsulation layer OEL. In addition, various functional layers, such as a touch sensing layer, a color filter layer, a light-collecting layer, or the like may be additionally arranged on the encapsulation layer ENC.

FIG. 7 is a plan view illustrating an example of horizontal transmission lines and vertical transmission lines included in a display panel according to one or more embodiments.

Hereinafter, an example of an arrangement structure and a connection relationship of horizontal transmission lines HTL and vertical transmission lines VTL included in the display panel DP will be described with reference to FIG. 7. Some of the horizontal transmission lines HTL and some of the vertical transmission lines VTL may constitute each of the first to (2M)th mesh lines ML_1 to ML_2M of FIG. 5.

For example, FIG. 7 may schematically illustrate twelve pixel circuits PC1 to PC12 arranged in one of the first to (2M)th display areas DA_1 to DA_2M of FIG. 5, and the horizontal transmission lines HTL and the vertical transmission lines VTL adjacent thereto. First to twelfth pixel circuits PC1 to PC12 may be arranged in the first direction DR1. The first to third pixel circuits PC1, PC2, and PC3 that are adjacent to each other may form a first unit pixel circuit UPC1, the fourth to sixth pixel circuits PC4, PC5, and PC6 that are adjacent to each other may form a second unit pixel circuit UPC2, the seventh to ninth pixel circuits PC7, PC8, and PC9 that are adjacent to each other may form a third unit pixel circuit UPC3, and the tenth to twelfth pixel circuits PC10, PC11, and PC12 that are adjacent to each other may form a fourth unit pixel circuit UPC4. That is, FIG. 7 may illustrate four unit pixel circuits UPC1, UPC2, UPC3, and UPC4 arranged in the first direction DR1.

In one or more embodiments, the horizontal transmission lines HTL may each extend in the first direction DR1, and may be spaced apart from each other in the second direction DR2. In one or more embodiments, the horizontal transmission lines HTL may include a horizontal high power transmission line HPDL, a horizontal low power transmission line HPSL, a first horizontal signal transmission line HSL1, a second horizontal signal transmission line HSL2, and a third horizontal signal transmission line HSL3.

In one or more embodiments, the vertical transmission lines VTL may each extend in the second direction DR2, and may be spaced apart from each other in the first direction DR1. The vertical transmission lines VTL may be in a different layer from the horizontal transmission lines HTL. For example, the horizontal transmission lines HTL may be in a same layer as the first contact electrode CE1 and the second contact electrode CE2 of FIG. 6, and the vertical transmission lines VTL may be in a same layer as the connection electrode CNE of FIG. 6, but the present disclosure is not limited thereto.

In one or more embodiments, the vertical transmission lines VTL may include a vertical high power transmission line VPDL, a vertical low power transmission line VPSL, a first vertical signal transmission line VSL1, a second vertical signal transmission line VSL2, and a third vertical signal transmission line VSL3.

For example, as illustrated in FIG. 7, one vertical transmission line VTL may be arranged corresponding to each of the first to twelfth pixel circuits PC1 to PC12. That is, twelve vertical transmission lines VTL may be arranged corresponding to twelve pixel circuits PC1 to PC12 (e.g., corresponding to four unit pixel circuits UPC1 to UPC4). For example, FIG. 7 illustrates that four vertical high power transmission lines VPDL, one vertical low power transmission line VPSL, five first vertical signal transmission lines VSL1, one second vertical signal transmission line VSL2, and one third vertical signal transmission line VSL3 are arranged corresponding to the first to twelfth pixel circuits PC1 to PC12, but this is only an example, and the present disclosure is not limited thereto.

The horizontal high power transmission line HPDL may be connected to the vertical high power transmission lines VPDL through contact holes. For example, the high power voltage (e.g., one of the first to (2M)th high power voltages VDD_1 to VDD_2M of FIG. 2) may be provided to the horizontal high power transmission line HPDL and the vertical high power transmission lines VPDL. The horizontal high power transmission line HPDL and the vertical high power transmission lines VPDL may be connected to adjacent pixels PX, and may transmit the high power voltage to the adjacent pixels PX.

The horizontal high power transmission lines HPDL and the vertical high power transmission lines VPDL connected to each other through contact holes may constitute the mesh line ML. The mesh line ML may be one of the first to (2M)th mesh lines ML_1 to ML_2M of FIG. 5. That is, the horizontal high power transmission lines HPDL may be the horizontal lines of each of the first to (2M)th mesh lines ML_1 to ML_2M, and the vertical high power transmission lines VPDL may be the vertical lines of each of the first to (2M)th mesh lines ML_1 to ML_2M. For example, the number of the vertical lines included in each of the first to (2M)th mesh lines ML_1 to ML_2M may be determined based on the number of the vertical high power transmission lines VPDL, which are allocated to transmit the high power voltage, among the vertical transmission lines VTL arranged in each of the first to (2M)th display areas DA_1 to DA_2M.

The horizontal low power transmission line HPSL may be connected to the vertical low power transmission line VPSL through a contact hole. The horizontal low power transmission line HPSL and the vertical low power transmission line VPSL may be connected to adjacent pixels PX and may transmit the low power voltage VSS of FIG. 4 to the adjacent pixels PX.

The first horizontal signal transmission line HSL1 may be connected to the first vertical signal transmission lines VSL1 through contact holes. The first horizontal signal transmission line HSL1 and the first vertical signal transmission lines VSL1 may be connected to adjacent pixels PX, and may transmit a first signal to the adjacent pixels PX.

The second horizontal signal transmission line HSL2 may be connected to the second vertical signal transmission line VSL2 through a contact hole. The second horizontal signal transmission line HSL2 and the second vertical signal transmission line VSL2 may be connected to adjacent pixels PX, and may transmit a second signal to the adjacent pixels PX.

The third horizontal signal transmission line HSL3 may be connected to the third vertical signal transmission line VSL3 through a contact hole. The third horizontal signal transmission line HSL3 and the third vertical signal transmission line VSL3 may be connected to adjacent pixels PX and may transmit a third signal to the adjacent pixels PX.

FIG. 8 is a plan view schematically illustrating an example of a portion of a display panel according to one or more embodiments.

Hereinafter, embodiments of the present disclosure will be described in more detail with corresponding examples. For example, FIG. 8 may selectively illustrate four left display areas DA_1 to DA_4 among the display areas of FIG. 5, in which the display panel DP includes eight display areas (e.g., M is 4). However, this is only an example and the present disclosure is not limited thereto. For example, the display panel DP may include nine or more display areas, for example, twenty-four display areas.

Referring to FIG. 8, in one or more embodiments, the first to fourth high power transmission lines VDTL_1 to VDTL_4 may be arranged in the non-display area NDA. Each of the first to fourth high power transmission lines VDTL_1 to VDTL_4 may extend in the first direction DR1. The first to fourth high power transmission lines VDTL_1 to VDTL_4 may be spaced apart from each other in the second direction DR2, and may be electrically insulated from (e.g., might not be electrically connected to) each other. For example, the first to fourth high power transmission lines VDTL_1 to VDTL_4 may be sequentially arranged in the second direction DR2. The first to fourth high power transmission lines VDTL_1 to VDTL_4 may receive the first to fourth high power voltages from the power management circuit PMC of FIG. 2, respectively.

The first to fourth display areas DA_1 to DA_4 may be located in the second direction DR2 from the first to fourth high power transmission lines VDTL_1 to VDTL_4. The first display area DA_1 may be located in the second direction DR2 from the first to fourth high power transmission lines VDTL_1 to VDTL_4, the second display area DA_2 may be located in the second direction DR2 from the first display area DA_1, the third display area DA_3 c may be located in the second direction DR2 from the second display area DA_2, and the fourth display area DA_4 may be located in the second direction DR2 from the third display area DA_3.

The first to fourth mesh lines ML_1 to ML_4 may be arranged in the first to fourth display areas DA_1 to DA_4, respectively. The first to fourth mesh lines ML_1 to ML_4 may be spaced apart from each other, and may be electrically insulated from (e.g., might not be electrically connected to) each other. Each of the first to fourth mesh lines ML_1 to ML_4 may include the horizontal lines each extending in the first direction DR1 and the vertical lines each extending in the second direction DR2, and the horizontal lines and the vertical lines may be electrically connected to each other.

The first connection lines DCL_1 may electrically connect the first high power transmission line VDTL_1 in the non-display area NDA and the first mesh line ML_1 in the first display area DA_1. Each of the first connection lines DCL_1 may extend in the second direction DR2.

In one or more embodiments, in a plan view, each of the first connection lines DCL_1 may overlap the first to fourth high power transmission lines VDTL_1 to VDTL_4. Each of the first connection lines DCL_1 may be electrically connected to the first high power transmission line VDTL_1 through a contact hole, and may be electrically insulated from (e.g., might not be electrically connected to) the second to fourth high power transmission lines VDTL_2 to VDTL_4.

In one or more embodiments, in a plan view, each of the first connection lines DCL_1 may overlap the first display area DA_1, and may not overlap the second to fourth display areas DA_2 to DA_4. That is, in a plan view, each of the first connection lines DCL_1 may be spaced apart from the second to fourth display areas DA_2 to DA_4. In other words, in a plan view, each of the first connection lines DCL_1 may overlap the first mesh line ML_1, and may not overlap the second to fourth mesh lines ML_2 to ML_4. That is, in a plan view, each of the first connection lines DCL_1 may be spaced apart from the second to fourth mesh lines ML_2 to ML_4.

Each of the first connection lines DCL_1 may be electrically connected to the first mesh line ML_1 through at least one contact hole, and may be electrically insulated from (e.g., might not be electrically connected to) the second to fourth mesh lines ML_2 to ML_4.

The second connection lines DCL_2 may electrically connect the second high power transmission line VDTL_2 in the non-display area NDA and the second mesh line ML_2 in the second display area DA_2. Each of the second connection lines DCL_2 may extend in the second direction DR2.

In one or more embodiments, in a plan view, each of the second connection lines DCL_2 may not overlap the first high power transmission line VDTL_1, and may overlap the second to fourth high power transmission lines VDTL_2 to VDTL_4. That is, in a plan view, each of the second connection lines DCL_2 may be spaced apart from the first high power transmission line VDTL_1. Each of the second connection lines DCL_2 may be electrically connected to the second high power transmission line VDTL_2 through a contact hole, and may be electrically insulated from (e.g., might not be electrically connected to) the first high power transmission line VDTL_1, the third high power transmission line VDTL_3, and the fourth high power transmission line VDTL_4.

In one or more embodiments, in a plan view, each of the second connection lines DCL_2 may overlap the first and second display areas DA_1 and DA_2, and may not overlap the third and fourth display areas DA_3 and DA_4. That is, in a plan view, each of the second connection lines DCL_2 may be spaced apart from the third and fourth display areas DA_3 and DA_4. In other words, in a plan view, each of the second connection lines DCL_2 may overlap the first and second mesh lines ML_1 and ML_2, and may not overlap the third and fourth mesh lines ML_3 and ML_4. That is, in a plan view, each of the second connection lines DCL_2 may be spaced apart from the third and fourth mesh lines ML_3 and ML_4.

Each of the second connection lines DCL_2 may be electrically connected to the second mesh line ML_2 through at least one contact hole, and may be electrically insulated from (e.g., might not be electrically connected to) the first mesh line ML_1, the third mesh line ML_3, and the fourth mesh line ML_4.

In one or more embodiments, a length of each of the second connection lines DCL_2 in the second direction DR2 may be greater than a length of each of the first connection lines DCL_1 in the second direction DR2.

The third connection lines DCL_3 may electrically connect the third high power transmission line VDTL_3 in the non-display area NDA and the third mesh line ML_3 in the third display area DA_3. Each of the third connection lines DCL_3 may extend in the second direction DR2.

In one or more embodiments, in a plan view, each of the third connection lines DCL_3 may not overlap the first and second high power transmission lines VDTL_1 and VDTL_2, and may overlap the third and fourth high power transmission lines VDTL_3 and VDTL_4. That is, in a plan view, each of the third connection lines DCL_3 may be spaced apart from the first and second high power transmission lines VDTL_1 and VDTL_2. Each of the third connection lines DCL_3 may be electrically connected to the third high power transmission line VDTL_3 through a contact hole, and may be electrically insulated from (e.g., might not be electrically connected to) the first high power transmission line VDTL_1, the second high power transmission line VDTL_2, and the fourth high power transmission line VDTL_4.

In one or more embodiments, in a plan view, each of the third connection lines DCL_3 may overlap the first to third display areas DA_1 to DA_3, and may not overlap the fourth display area DA_4. That is, in a plan view, each of the third connection lines DCL_3 may be spaced apart from the fourth display area DA_4. In other words, in a plan view, each of the third connection lines DCL_3 may overlap the first to third mesh lines ML_1 to ML_3, and may not overlap the fourth mesh line ML_4. That is, in a plan view, each of the third connection lines DCL_3 may be spaced apart from the fourth mesh line ML_4.

Each of the third connection lines DCL_3 may be electrically connected to the third mesh line ML_3 through at least one contact hole, and may be electrically insulated from (e.g., might not be electrically connected to) the first mesh line ML_1, the second mesh line ML_2, and the fourth mesh line ML_4.

In one or more embodiments, a length of each of the third connection lines DCL_3 in the second direction DR2 may be greater than the length of each of the first connection lines DCL_1 and the second connection lines DCL_2 in the second direction DR2.

The fourth connection lines DCL_4 may electrically connect the fourth high power transmission line VDTL_4 in the non-display area NDA and the fourth mesh line ML_4 in the fourth display area DA_4. Each of the fourth connection lines DCL_4 may extend in the second direction DR2.

In one or more embodiments, in a plan view, each of the fourth connection lines DCL_4 may not overlap the first to third high power transmission lines VDTL_1 to VDTL_3, and may overlap the fourth high power transmission line VDTL_4. That is, in a plan view, each of the fourth connection lines DCL_4 may be spaced apart from the first to third high power transmission lines VDTL_1 to VDTL_3. Each of the fourth connection lines DCL_4 may be electrically connected to the fourth high power transmission line VDTL_4 through a contact hole, and may be electrically insulated from (e.g., might not be electrically connected to) the first to third high power transmission lines VDTL_1 to VDTL_3.

In one or more embodiments, in a plan view, each of the fourth connection lines DCL_4 may overlap the first to fourth display areas DA_1 to DA_4. In other words, in a plan view, each of the fourth connection lines DCL_4 may overlap the first to fourth mesh lines ML_1 to ML_4.

Each of the fourth connection lines DCL_4 may be electrically connected to the fourth mesh line ML_4 through at least one contact hole, and may be electrically insulated from (e.g., might not be electrically connected to) the first to third mesh lines ML_1 to ML_3.

In one or more embodiments, a length of each of the fourth connection lines DCL_4 in the second direction DR2 may be greater than the length of each of the first connection lines DCL_1, the second connection lines DCL_2, and the third connection lines DCL_3 in the second direction DR2.

In one or more embodiments, the number of the first connection lines DCL_1, the number of the second connection lines DCL_2, the number of the third connection lines DCL_3, and the number of the fourth connection lines DCL_4 may be the same. FIG. 8 illustrates that six first connection lines DCL_1, six second connection lines DCL_2, six third connection lines DCL_3, and six fourth connection lines DCL_4 are arranged, for convenience, but the number of each of the first to fourth connection lines DCL_1, DCL_2, DCL_3, and DCL_4 is not limited thereto. For example, the total number of the first to fourth connection lines DCL_1, DCL_2, DCL_3, and DCL_4 may be determined based on the number of lines, which are allocated to transmit the high power voltage, among the vertical transmission lines VTL arranged in each of the first to (2M)th display areas DA_1 to DA_2M (see FIG. 7).

In one or more embodiments, the sum of the number of the vertical lines included in each of the first to fourth mesh lines ML_1 to ML_4 and the number of the first to fourth connection lines DCL_1, DCL_2, DCL_3, and DCL_4 respectively overlapping the first to fourth mesh lines ML_1 to ML_4 may be constant. For example, the sum of the number of the vertical lines included in the first mesh line ML_1 and the number of the first to fourth connection lines DCL_1, DCL_2, DCL_3, and DCL_4 that overlap the first mesh line ML_1 (e.g., overlap the first display area DA_1), the sum of the number of the vertical lines included in the second mesh line ML_2 and the number of the second to fourth connection lines DCL_2, DCL_3, and DCL_4 that overlap the second mesh line ML_2 (e.g., overlap the second display area DA_2), the sum of the number of the vertical lines included in the third mesh line ML_3 and the number of the third and fourth connection lines DCL_3 and DCL_4 that overlap the third mesh line ML_3 (e.g., overlap the third display area DA_3), and the sum of the number of the vertical lines included in the fourth mesh line ML_4 and the number of the fourth connection line DCL_4 that overlap the fourth mesh line ML_4 (e.g. overlaps the fourth display area DA_4) may be equal.

In one or more embodiments, as illustrated in FIG. 8, a virtual reference line RL, which extends in the second direction DR2 and passes through centers of the first to fourth display areas DA_1 to DA_4, may be defined. The first to fourth connection lines DCL_1, DCL_2, DCL_3, and DCL_4 may be arranged to be symmetrical with respect to the virtual reference line RL in the first direction DR1. That is, the first to fourth connection lines DCL_1, DCL_2, DCL_3, and DCL_4 may be arranged to constitute one connection line group DCG that is symmetrical with respect to one virtual reference line RL in the first direction DR1.

In one or more embodiments, the first connection lines DCL_1 may include first-first connection lines DCL_1-1 and first-second connection lines DCL_1-2. The first-first connection lines DCL_1-1 may be adjacent to each other in the first direction DR1.

The first-second connection lines DCL_1-2 may be adjacent to each other in the first direction DR1, and may be symmetrically arranged with the first-first connection lines DCL_1-1 with respect to the virtual reference line RL in the first direction DR1.

In one or more embodiments, the second connection lines DCL_2 may include second-first connection lines DCL_2-1 and second-second connection lines DCL_2-2. The second-first connection lines DCL_2-1 may be adjacent to each other in the first direction DR1, and may be arranged between the first-first connection lines DCL_1-1 and the virtual reference line RL. The second-first connection lines DCL_2-1 may be adjacent to the first-first connection lines DCL_1-1.

The second-second connection lines DCL_2-2 may be adjacent to each other in the first direction DR1, and may be symmetrically arranged with the second-first connection lines DCL_2-1 with respect to the virtual reference line RL in the first direction DR1. The second-second connection lines DCL_2-2 may be arranged between the first-second connection lines DCL_1-2 and the virtual reference line RL. The second-second connection lines DCL_2-2 may be adjacent to the first-second connection lines DCL_1-2.

In one or more embodiments, the third connection lines DCL_3 may include third-first connection lines DCL_3-1 and third-second connection lines DCL_3-2. The third-first connection lines DCL_3-1 may be adjacent to each other in the first direction DR1, and may be arranged between the second-first connection lines DCL_2-1 and the virtual reference line RL. The third-first connection lines DCL_3-1 may be adjacent to the second-first connection lines DCL_2-1.

The third-second connection lines DCL_3-2 may be adjacent to each other in the first direction DR1, and may be symmetrically arranged with the third-first connection lines DCL_3-1 with respect to the virtual reference line RL in the first direction DR1. The third-second connection lines DCL_3-2 may be arranged between the second-second connection lines DCL_2-2 and the virtual reference line RL. The third-second connection lines DCL_3-2 may be adjacent to the second-second connection lines DCL_2-2.

In one or more embodiments, the fourth connection lines DCL_4 may include fourth-first connection lines DCL_4-1 and fourth-second connection lines DCL_4-2. The fourth-first connection lines DCL_4-1 may be adjacent to each other in the first direction DR1, and may be arranged between the third-first connection lines DCL_3-1 and the virtual reference line RL. The fourth-first connection lines DCL_4-1 may be adjacent to the third-first connection lines DCL_3-1.

The fourth-second connection lines DCL_4-2 may be adjacent to each other in the first direction DR1, and may be symmetrically arranged with the fourth-first connection lines DCL_4-1 with respect to the virtual reference line RL in the first direction DR1. The fourth-second connection lines DCL_4-2 may be arranged between the third-second connection lines DCL_3-2 and the virtual reference line RL. The fourth-second connection lines DCL_4-2 may be adjacent to the third-second connection lines DCL_3-2.

In one or more embodiments, the number of the first-first connection lines DCL_1-1, the number of the first-second connection lines DCL_1-2, the number of the second-first connection lines DCL_2-1, the number of the second-second connection lines DCL_2-2, the number of the third-first connection lines DCL_3-1, the number of the third-second connection lines DCL_3-2, the number of the fourth-first connection lines DCL_4-1, and the number of the fourth-second connection lines DCL_4-2 may be equal to each other.

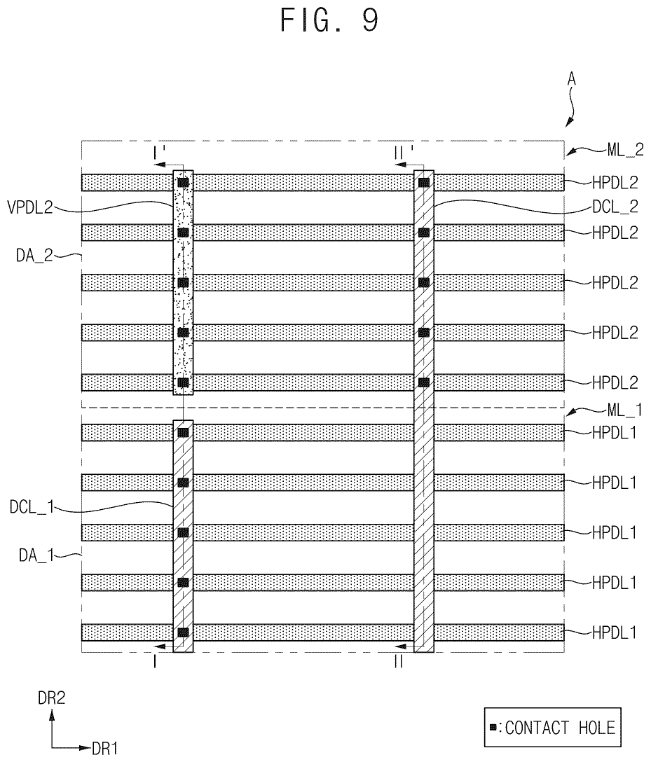

Each of the first connection lines DCL_1 may be connected to at least one of first horizontal lines (e.g., first horizontal lines HPDL1 of FIG. 9) included in the first mesh line ML_1 through a contact hole. Similarly, each of the second connection lines DCL_2 may be connected to at least one of second horizontal lines (e.g., second horizontal lines HPDL2 of FIG. 9) included in the second mesh line ML_2 through a contact hole, each of the third connection lines DCL_3 may be connected to at least one of third horizontal lines included in the third mesh line ML_3 through a contact hole, and each of the fourth connection lines DCL_4 may be connected to at least one of fourth horizontal lines included in the fourth mesh line ML_4 through a contact hole.

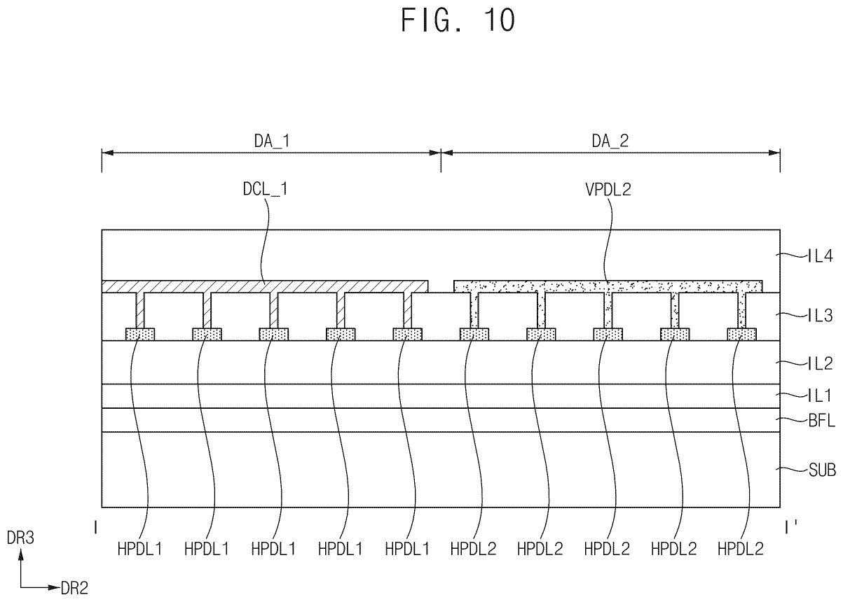

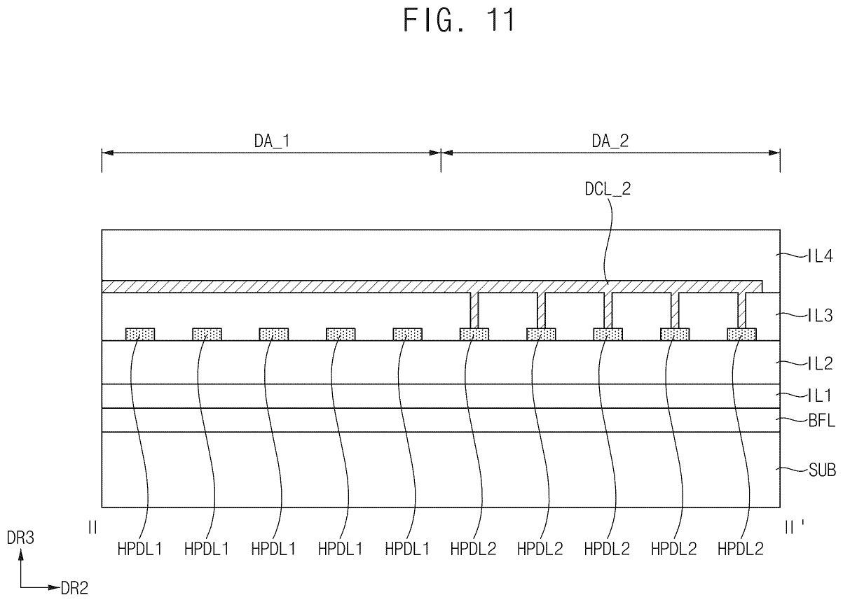

FIG. 9 is an enlarged plan view of area A of FIG. 8. FIG. 10 is a cross-sectional view taken along line I-I′ of FIG. 9. FIG. 11 is a cross-sectional view taken along line II-II′ of FIG. 9.

Hereinafter, the connection relationship between each of the first connection lines DCL_1 and the first mesh line ML_1, and the connection relationship between each of the second connection lines DCL_2 and the second mesh line ML_2, will be representatively described in detail with reference to FIGS. 9 to 11.

Referring to FIGS. 8 to 12, the first mesh line ML_1 may include the first horizontal lines HPDL1 each extending in the first direction DR1. The second mesh line ML_2 may include the second horizontal lines HPDL2 each extending in the first direction DR1 and first vertical lines VPDL2 each extending in the second direction DR2. FIGS. 8 and 9 illustrate that the first mesh line ML_1 includes five first horizontal lines HPDL1 and the second mesh line ML_2 includes five second horizontal lines HPDL2, but the number of each of the first horizontal lines HPDL1 and the second horizontal lines HPDL2 is not limited thereto.

In a plan view, each of the first connection lines DCL_1 may overlap the first horizontal lines HPDL1. In one or more embodiments, each of the first connection lines DCL_1 may be electrically connected to all of the first horizontal lines HPDL1 through contact holes. In one or more embodiments, in the first display area DA_1, the first connection lines DCL_1 may also function as the vertical lines of the first mesh line ML_1. In a plan view, each of the first connection lines DCL_1 may not overlap the second horizontal lines HPDL2. That is, in a plan view, each of the first connection lines DCL_1 may be spaced apart from the second horizontal lines HPDL2.

In a plan view, each of the second connection lines DCL_2 may overlap the first horizontal lines HPDL1 and the second horizontal lines HPDL2. Each of the second connection lines DCL_2 may be electrically insulated from (e.g., might not be electrically connected to) the first horizontal lines HPDL1. In one or more embodiments, each of the second connection lines DCL_2 may be electrically connected to all of the second horizontal lines HPDL2 through contact holes.

In a plan view, each of the second vertical lines VPDL2 may overlap the second horizontal lines HPDL2. In one or more embodiments, each of the second vertical lines VPDL2 may be electrically connected to all of the second horizontal lines HPDL2 through contact holes.

In one or more embodiments, the first horizontal lines HPDL1 and the second horizontal lines HPDL2 may be in the same layer. The first connection lines DCL_1, the second connection lines DCL_2, and the second vertical lines VPDL2 may be in the same layer. The first connection lines DCL_1, the second connection lines DCL_2, and the second vertical lines VPDL2 may be in a different layer from the first horizontal lines HPDL1 and the second horizontal lines HPDL2. For example, as illustrated in FIGS. 10 and 11, the first horizontal lines HPDL1 and the second horizontal lines HPDL2 may be arranged in the same layer as the first contact electrode CE1 and the second contact electrode CE2 of FIG. 6, and the first connection lines DCL_1, the second connection lines DCL_2, and the second vertical lines VPDL2 may be arranged in the same layer as the connection electrode CNE of FIG. 6, but the present disclosure is not limited thereto.

In one or more embodiments, as illustrated in FIGS. 8 and 9, one of the second vertical lines VPDL2 in the second display area DA_2 may overlap one of the first connection lines DCL_1 in the first display area DA_1 in the second direction DR2. That is, one of the second vertical lines VPDL2 in the second display area DA_2 may be in a same column as one of the first connection lines DCL_1 in the first display area DA_1.

In one or more embodiments, as illustrated in FIG. 8, each of the third connection lines DCL_3 may be electrically connected to all of the third horizontal lines included in the third mesh line ML_3 through contact holes, and each of the fourth connection lines DCL_4 may be electrically connected to all of the fourth horizontal lines included in the fourth mesh line ML_4 through contact holes.

The connection relationship and the arrangement structure of the connection lines DCL_1 to DCL_4 and the mesh lines ML_1 to ML_4 according to one or more embodiments have been described with reference to FIGS. 8 to 11, this is only an example and the present disclosure is not limited thereto, and the connection relationship and the arrangement structure of the connection lines DCL_1 to DCL_4 and the mesh lines ML_1 to ML_4 may be variously changed.

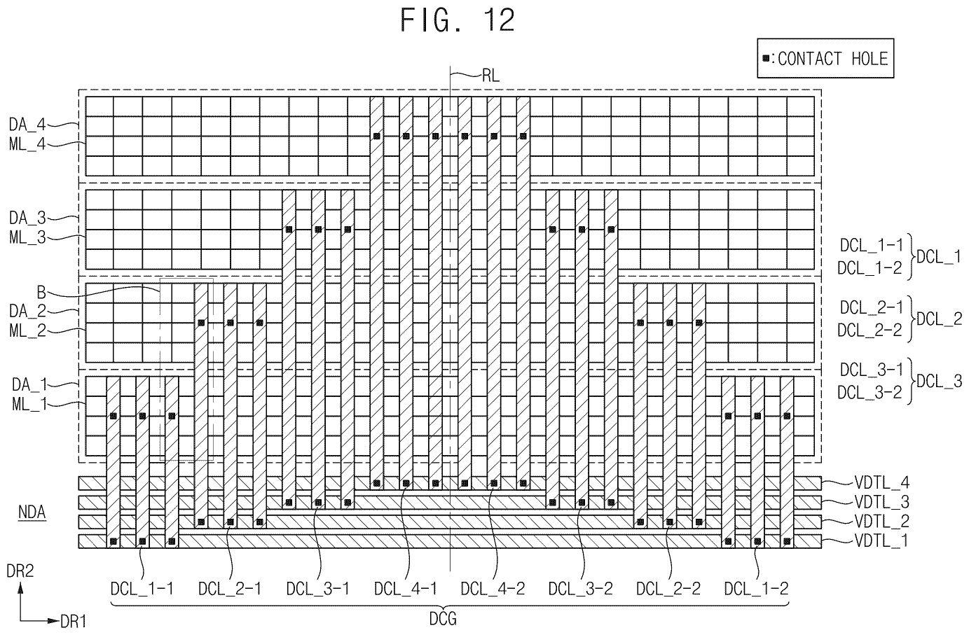

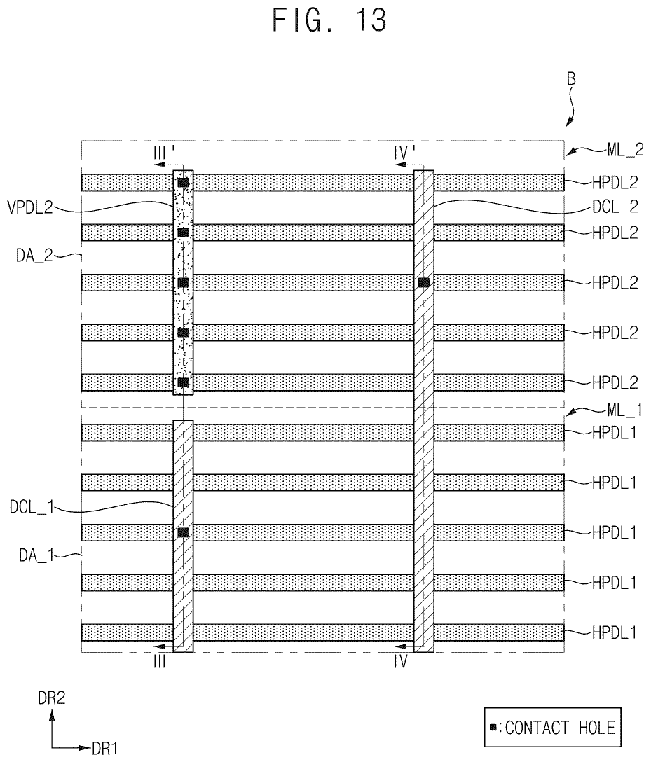

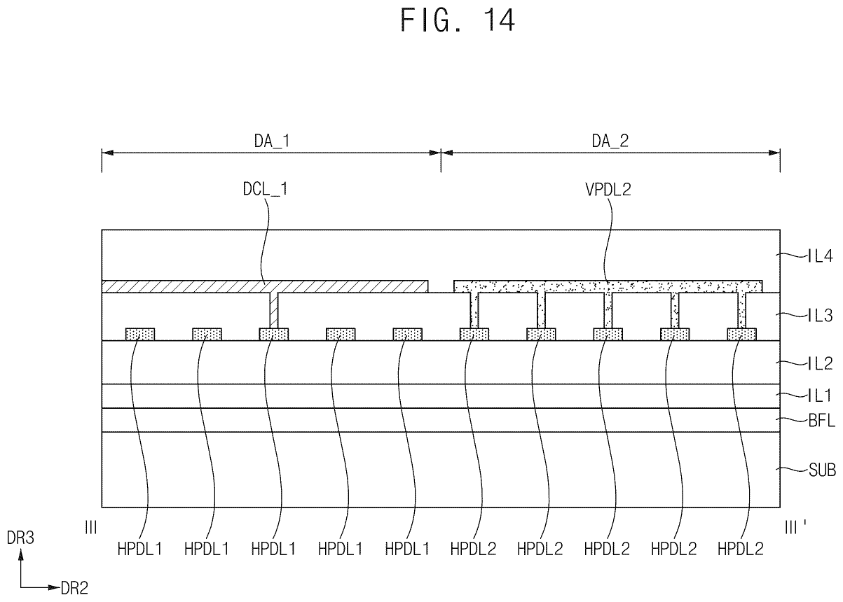

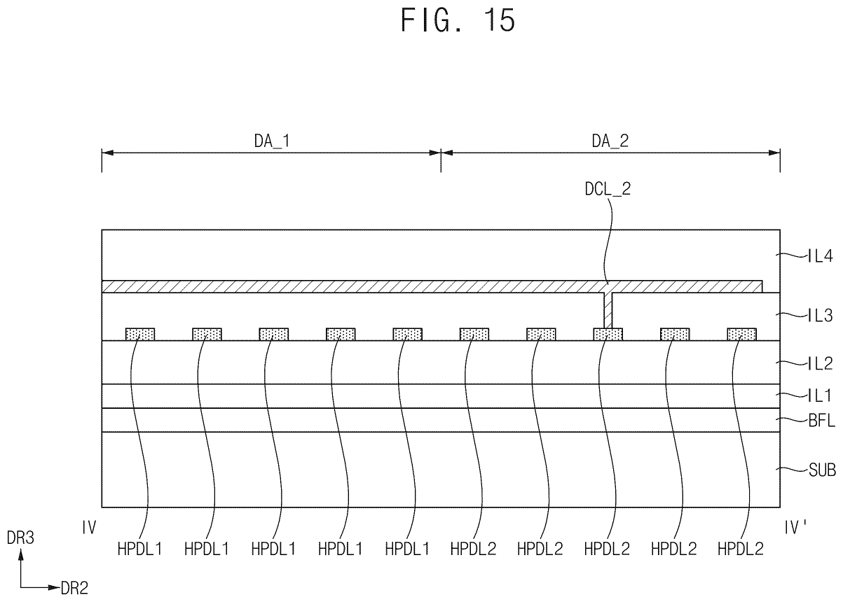

FIG. 12 is a plan view schematically illustrating another example of a portion of a display panel according to one or more embodiments. FIG. 13 is an enlarged plan view of area B of FIG. 12. FIG. 14 is a cross-sectional view taken along line III-III′ of FIG. 13. FIG. 15 is a cross-sectional view taken along line IV-IV′ of FIG. 13.

Referring to FIGS. 12 to 15, in one or more embodiments, each of the first connection lines DCL_1 may be connected to some of the first horizontal lines HPDL1 included in the first mesh line ML_1 through contact holes, and may not be connected to the remaining first horizontal lines HPDL1. For example, each of the first connection lines DCL_1 may be electrically connected to some of the first horizontal lines HPDL1 included in the first mesh line ML_1, which are arranged at a central portion of the first display area DA_1 in the second direction DR2 (e.g., third first horizontal line HPDL1 from the bottom in FIG. 13), through contact holes, and may not be connected to the remaining first horizontal lines HPDL1, which are arranged at both side portions of the first display area DA_1 in the second direction DR2.

Similarly, in one or more embodiments, each of the second connection lines DCL_2 may be connected to some of the second horizontal lines HPDL2 included in the second mesh line ML_2 through contact holes, and may not be connected to the remaining second horizontal lines HPDL2. For example, each of the second connection lines DCL_2 may be electrically connected to some of the second horizontal lines HPDL2 included in the second mesh line ML_2, which are arranged at a central portion of the second display area DA_2 in the second direction DR2 (e.g., third second horizontal line HPDL2 from the top in FIG. 13), through contact holes, and may not be connected to the remaining second horizontal lines HPDL2, which are arranged at both side portions of the second display area DA_2 in the second direction DR2. Each of the second vertical lines VPDL2 included in the second mesh line ML_2 may be electrically connected to all of the second horizontal lines HPDL2 through contact holes.

Similarly, in one or more embodiments, each of the third connection lines DCL_3 may be connected to some of the third horizontal lines included in the third mesh line ML_3 through contact holes, and may not be connected to the remaining third horizontal lines. For example, each of the third connection lines DCL_3 may be electrically connected to some of the third horizontal lines included in the third mesh line ML_3, which are arranged at a central portion of the third display area DA_3 in the second direction DR2, through contact holes, and may not be connected to the remaining third horizontal lines, which are arranged at both side portions of the third display area DA_3 in the second direction DR2. Each of the third vertical lines included in the third mesh line ML_3 may be electrically connected to all of the third horizontal lines through contact holes.

Similarly, in one or more embodiments, each of the fourth connection lines DCL_4 may be connected to some of the fourth horizontal lines included in the fourth mesh line ML_4 through contact holes, and may not be connected to the remaining fourth horizontal lines. For example, each of the fourth connection lines DCL_4 may be electrically connected to some of the fourth horizontal lines included in the fourth mesh line ML_4, which are arranged at a central portion of the fourth display area DA_4 in the second direction DR2, through contact holes, and may not be connected to the remaining fourth horizontal lines, which are arranged at both side portions of the fourth display area DA_4 in the second direction DR2. Each of the fourth vertical lines included in the fourth mesh line ML_4 may be electrically connected to all of the fourth horizontal lines through contact holes.

FIG. 12 illustrates that each of the connection lines DCL_1, DCL_2, DCL_3, and DCL_4 is electrically connected one horizontal line through a contact hole, but each of the connection lines DCL_1, DCL_2, DCL_3, and DCL_4 may be electrically connected two or more horizontal lines which are arranged in the central portion through contact holes.

According to the embodiments of FIGS. 12 to 15, in each of the first to fourth display areas DA_1 to DA_4, the deviation in the voltage drop of the high power voltage between an area near the first to fourth high power transmission lines VDTL_1 to VDTL_4 and an area that is farther away (e.g., areas divided along the first direction DR1) may be prevented or reduced. Accordingly, recognition of a boundary between the first to fourth display areas DA_1 to DA_4 may be prevented or reduced, thus a display quality of the display device may be improved.

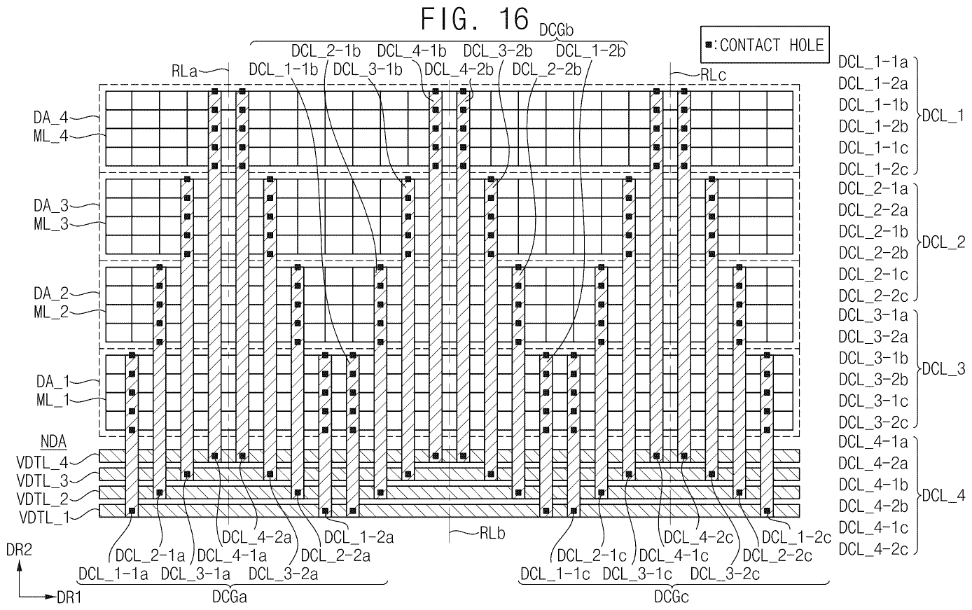

FIG. 16 is a plan view schematically illustrating still another example of a portion of a display panel according to one or more embodiments.

Referring to FIG. 16, in one or more embodiments, virtual reference lines RLa, RLb, and RLc, which each extend in the second direction DR2 and which are spaced apart from each other in the first direction DR1, may be defined. Some of the first to fourth connection lines DCL_1, DCL_2, DCL_3, and DCL_4 may be arranged to be symmetrical with respect to each of the virtual reference lines RLa, RLb, and RLc in the first direction DR1. That is, the first to fourth connection lines DCL_1, DCL_2, DCL_3, and DCL_4 may be arranged to constitute a plurality of connection line groups DCGa, DCGb, and DCGc, each of which is symmetrical with respect to corresponding one of the virtual reference lines RLa, RLb, and RLc in the first direction DR1.

FIG. 16 illustrates that three virtual reference lines RLa, RLb, and RLc are defined and the first to fourth connection lines DCL_1, DCL_2, DCL_3, and DCL_4 constitute three connection line groups DCGa, DCGb, and DCGc, for convenience, but this is only an example and the present disclosure is not limited thereto. For example, four or more, for example, ten, virtual reference lines may be defined, and correspondingly, the first to fourth connection lines DCL_1, DCL_2, DCL_3, and DCL_4 may constitute four or more, for example, ten, connection line groups.

Each of the first to third virtual reference lines RLa, RLb, and RLc may extend in the second direction DR2 so as to pass through the first to fourth display areas DA_1 to DA_4, and may be spaced apart from each other in the first direction DR1. For example, the first to third virtual reference lines RLa, RLb, and RLc may be spaced apart from each other at a constant distance.

In one or more embodiments, the first connection lines DCL_1 may include a first-first connection line DCL_1-1a, a first-second connection line DCL_1-2a, a first-third connection line DCL_1-1b, a first-fourth connection line DCL_1-2b, a first-fifth connection line DCL_1-1c, and a first-sixth connection line DCL_1-2c. FIG. 16 illustrates one first-first connection line DCL_1-1a, one first-second connection line DCL_1-2a, one first-third connection line DCL_1-1b, one first-fourth connection line DCL_1-2b, one first-fifth connection line DCL_1-1c, and one first-sixth connection line DCL_1-2c, for convenience, but the present disclosure is not limited thereto.

For example, a plurality of first-first connection lines DCL_1-1a may be arranged adjacent to each other in the first direction DR1, a plurality of first-second connection lines DCL_1-2a may be arranged adjacent to each other in the first direction DR1, a plurality of first-third connection lines DCL_1-1b may be arranged adjacent to each other in the first direction DR1, a plurality of first-fourth connection lines DCL_1-2b may be arranged adjacent to each other in the first direction DR1, a plurality of first-fifth connection lines DCL_1-1c may be arranged adjacent to each other in the first direction DR1, and a plurality of first-sixth connection lines DCL_1-2c may be arranged adjacent to each other in the first direction DR1.

The first-second connection line DCL_1-2a may be symmetrically arranged with the first-first connection line DCL_1-1a with respect to the first virtual reference line RLa in the first direction DR1.

The first-third connection line DCL_1-1b may be arranged between the first-second connection line DCL_1-2a and the second virtual reference line RLb. The first-third connection line DCL_1-1b may be adjacent to the first-second connection line DCL_1-2a.

The first-fourth connection line DCL_1-2b may be symmetrically arranged with the first-third connection line DCL_1-1b with respect to the second virtual reference line RLb in the first direction DR1.

The first-fifth connection line DCL_1-1c may be arranged between the first-fourth connection line DCL_1-2b and the third virtual reference line RLc. The first-fifth connection line DCL_1-1c may be adjacent to the first-fourth connection line DCL_1-2b.

The first-sixth connection line DCL_1-2c may be symmetrically arranged with the first-fifth connection line DCL_1-1c with respect to the third virtual reference line RLc in the first direction DR1.

In one or more embodiments, the second connection lines DCL_2 may include a second-first connection line DCL_2-1a, a second-second connection line DCL_2-2a, a second-third connection line DCL_2-1b, a second-fourth connection line DCL_2-2b, a second-fifth connection line DCL_2-1c, and a second-sixth connection line DCL_2-2c. FIG. 16 illustrates one second-first connection line DCL_2-1a, one second-second connection line DCL_2-2a, one second-third connection line DCL_2-1b, one second-fourth connection line DCL_2-2b, one second-fifth connection line DCL_2-1c, and one second-sixth connection line DCL_2-2c, for convenience, but the present disclosure is not limited thereto.

For example, a plurality of second-first connection lines DCL_2-1a may be arranged adjacent to each other in the first direction DR1, a plurality of second-second connection lines DCL_2-2a may be arranged adjacent to each other in the first direction DR1, a plurality of second-third connection lines DCL_2-1b may be arranged adjacent to each other in the first direction DR1, a plurality of second-fourth connection lines DCL_2-2b may be arranged adjacent to each other in the first direction DR1, a plurality of second-fifth connection lines DCL_2-1c may be arranged adjacent to each other in the first direction DR1, and a plurality of second-sixth connection lines DCL_2-2c may be arranged adjacent to each other in the first direction DR1.

The second-first connection line DCL_2-1a may be arranged between the first-first connection line DCL_1-1a and the first virtual reference line RLa. The second-first connection line DCL_2-1a may be adjacent to the first-first connection line DCL_1-1a.

The second-second connection line DCL_2-2a may be symmetrically arranged with the second-first connection line DCL_2-1a with respect to the first virtual reference line RLa in the first direction DR1. The second-second connection line DCL_2-2a may be arranged between the first-second connection line DCL_1-2a and the first virtual reference line RLa. The second-second connection line DCL_2-2a may be adjacent to the first-second connection line DCL_1-2a.

The second-third connection line DCL_2-1b may be arranged between the first-third connection line DCL_1-1b and the second virtual reference line RLb. The second-third connection line DCL_2-1b may be adjacent to the first-third connection line DCL_1-1b.

The second-fourth connection line DCL_2-2b may be symmetrically arranged with the second-third connection line DCL_2-1b with respect to the second virtual reference line RLb in the first direction DR1. The second-fourth connection line DCL_2-2b may be arranged between the first-fourth connection line DCL_1-2b and the second virtual reference line RLb. The second-fourth connection line DCL_2-2b may be adjacent to the first-fourth connection line DCL_1-2b.

The second-fifth connection line DCL_2-1c may be arranged between the first-fifth connection line DCL_1-1c and the third virtual reference line RLc. The second-fifth connection line DCL_2-1c may be adjacent to the first-fifth connection line DCL_1-1c.

The second-sixth connection line DCL_2-2c may be symmetrically arranged with the second-fifth connection line DCL_2-1c with respect to the third virtual reference line RLc in the first direction DR1. The second-sixth connection line DCL_2-2c may be arranged between the first-sixth connection line DCL_1-2c and the third virtual reference line RLc. The second-sixth connection line DCL_2-2c may be adjacent to the first-sixth connection line DCL_1-2c.

In one or more embodiments, the third connection lines DCL_3 may include a third-first connection line DCL_3-1a, a third-second connection line DCL_3-2a, a third-third connection line DCL_3-1b, a third-fourth connection line DCL_3-2b, a third-fifth connection line DCL_3-1c, and a third-sixth connection line DCL_3-2c. FIG. 16 illustrates one third-first connection line DCL_3-1a, one third-second connection line DCL_3-2a, one third-third connection line DCL_3-1b, one third-fourth connection line DCL_3-2b, one third-fifth connection line DCL_3-1c, and one third-sixth connection line DCL_3-2c, for convenience, but the present disclosure is not limited thereto.

For example, a plurality of third-first connection lines DCL_3-1a may be arranged adjacent to each other in the first direction DR1, a plurality of third-second connection lines DCL_3-2a may be arranged adjacent to each other in the first direction DR1, a plurality of third-third connection lines DCL_3-1b may be arranged adjacent to each other in the first direction DR1, a plurality of third-fourth connection lines DCL_3-2b may be arranged adjacent to each other in the first direction DR1, a plurality of third-fifth connection lines DCL_3-1c may be arranged adjacent to each other in the first direction DR1, and a plurality of third-sixth connection lines DCL_3-2c may be arranged adjacent to each other in the first direction DR1.

The third-first connection line DCL_3-1a may be arranged between the second-first connection line DCL_2-1a and the first virtual reference line RLa. The third-first connection line DCL_3-1a may be adjacent to the second-first connection line DCL_2-1a.

The third-second connection line DCL_3-2a may be symmetrically arranged with the third-first connection line DCL_3-1a with respect to the first virtual reference line RLa in the first direction DR1. The third-second connection line DCL_3-2a may be arranged between the second-second connection line DCL_2-2a and the first virtual reference line RLa. The third-second connection line DCL_3-2a may be adjacent to the second-second connection line DCL_2-2a.

The third-third connection line DCL_3-1b may be arranged between the second-third connection line DCL_2-1b and the second virtual reference line RLb. The third-third connection line DCL_3-1b may be adjacent to the second-third connection line DCL_2-1b.

The third-fourth connection line DCL_3-2b may be symmetrically arranged with the third-third connection line DCL_3-1b with respect to the second virtual reference line RLb in the first direction DR1. The third-fourth connection line DCL_3-2b may be arranged between the second-fourth connection line DCL_2-2b and the second virtual reference line RLb. The third-fourth connection line DCL_3-2b may be adjacent to the second-fourth connection line DCL_2-2b.

The third-fifth connection line DCL_3-1c may be arranged between the second-fifth connection line DCL_2-1c and the third virtual reference line RLc. The third-fifth connection line DCL_3-1c may be adjacent to the second-fifth connection line DCL_2-1c.

The third-sixth connection line DCL_3-2c may be symmetrically arranged with the third-fifth connection line DCL_3-1c with respect to the third virtual reference line RLc in the first direction DR1. The third-sixth connection line DCL_3-2c may be arranged between the second-sixth connection line DCL_2-2c and the third virtual reference line RLc. The third-sixth connection line DCL_3-2c may be adjacent to the second-sixth connection line DCL_2-2c.

In one or more embodiments, the fourth connection lines DCL_4 may include a fourth-first connection line DCL_4-1a, a fourth-second connection line DCL_4-2a, a fourth-third connection line DCL_4-1b, a fourth-fourth connection line DCL_4-2b, a fourth-fifth connection line DCL_4-1c, and a fourth-sixth connection line DCL_4-2c. FIG. 16 illustrates one fourth-first connection line DCL_4-1a, one fourth-second connection line DCL_4-2a, one fourth-third connection line DCL_4-1b, one fourth-fourth connection line DCL_4-2b, one fourth-fifth connection line DCL_4-1c, and one fourth-sixth connection line DCL_4-2c, for convenience, but the present disclosure is not limited thereto.

For example, a plurality of fourth-first connection lines DCL_4-1a may be arranged adjacent to each other in the first direction DR1, a plurality of fourth-second connection lines DCL_4-2a may be arranged adjacent to each other in the first direction DR1, a plurality of fourth-third connection lines DCL_4-1b may be arranged adjacent to each other in the first direction DR1, a plurality of fourth-fourth connection lines DCL_4-2b may be arranged adjacent to each other in the first direction DR1, a plurality of fourth-fifth connection lines DCL_4-1c may be arranged adjacent to each other in the first direction DR1, and a plurality of fourth-sixth connection lines DCL_4-2c may be arranged adjacent to each other in the first direction DR1.

The fourth-first connection line DCL_4-1a may be arranged between the third-first connection line DCL_3-1a and the first virtual reference line RLa. The fourth-first connection line DCL_4-1a may be adjacent to the third-first connection line DCL_3-1a.

The fourth-second connection line DCL_4-2a may be symmetrically arranged with the fourth-first connection line DCL_4-1a with respect to the first virtual reference line RLa in the first direction DR1. The fourth-second connection line DCL_4-2a may be arranged between the third-second connection line DCL_3-2a and the first virtual reference line RLa. The fourth-second connection line DCL_4-2a may be adjacent to the third-second connection line DCL_3-2a and the fourth-first connection line DCL_4-1a.

The fourth-third connection line DCL_4-1b may be arranged between the third-third connection line DCL_3-1b and the second virtual reference line RLb. The fourth-third connection line DCL_4-1b may be adjacent to the third-third connection line DCL_3-1b.

The fourth-fourth connection line DCL_4-2b may be symmetrically arranged with the fourth-third connection line DCL_4-1b with respect to the second virtual reference line RLb in the first direction DR1. The fourth-fourth connection line DCL_4-2b may be arranged between the third-fourth connection line DCL_3-2b and the second virtual reference line RLb. The fourth-fourth connection line DCL_4-2b may be adjacent to the third-fourth connection line DCL_3-2b and the fourth-third connection line DCL_4-1b.

The fourth-fifth connection line DCL_4-1c may be arranged between the third-fifth connection line DCL_3-1c and the third virtual reference line RLc. The fourth-fifth connection line DCL_4-1c may be adjacent to the third-fifth connection line DCL_3-1c.

The fourth-sixth connection line DCL_4-2c may be symmetrically arranged with the fourth-fifth connection line DCL_4-1c with respect to the third virtual reference line RLc in the first direction DR1. The fourth-sixth connection line DCL_4-2c may be arranged between the third-sixth connection line DCL_3-2c and the third virtual reference line RLc. The fourth-sixth connection line DCL_4-2c may be adjacent to the third-sixth connection line DCL_3-2c and the fourth-fifth connection line DCL_4-1c.

The first-first connection line DCL_1-1a, the first-second connection line DCL_1-2a, the second-first connection line DCL_2-1a, the second-second connection line DCL_2-2a, the third-first connection line DCL_3-1a, the third-second connection line DCL_3-2a, the fourth-first connection line DCL_4-1a, and the fourth-second connection line DCL_4-2a, which are adjacent to each other in the first direction DR1, may constitute the first connection line group DCGa.

The first-third connection line DCL_1-1b, the first-fourth connection line DCL_1-2b, the second-third connection line DCL_2-1b, the second-fourth connection line DCL_2-2b, the third-third connection line DCL_3-1b, the third-fourth connection line DCL_3-2b, the fourth-third connection line DCL_4-1b, and the fourth-fourth connection line DCL_4-2b, which are adjacent to each other in the first direction DR1, may constitute the second connection line group DCGb.

The first-fifth connection line DCL_1-1c, the first-sixth connection line DCL_1-2c, the second-fifth connection line DCL_2-1c, the second-sixth connection line DCL_2-2c, the third-fifth connection line DCL_3-1c, the third-sixth connection line DCL_3-2c, the fourth-fifth connection line DCL_4-1c, and the fourth-sixth connection line DCL_4-2c, which are adjacent to each other in the first direction DR1, may constitute the third connection line group DCGc.

Each of the first connection lines DCL_1 may be connected to at least one of the first horizontal lines included in the first mesh line ML_1 through a contact hole. Each of the second connection lines DCL_2 may be connected to at least one of the second horizontal lines included in the second mesh line ML_2 through a contact hole. Each of the third connection lines DCL_3 may be connected to at least one of the third horizontal lines included in the third mesh line ML_3 through a contact hole. Each of the fourth connection lines DCL_4 may be connected to at least one of the fourth horizontal lines included in the fourth mesh line ML_4 through a contact hole.

In one or more embodiments, as illustrated in FIG. 16, each of the first connection lines DCL_1 may be electrically connected to all of the first horizontal lines included in the first mesh line ML_1 through contact holes. Each of the second connection lines DCL_2 may be electrically connected to all of the second horizontal lines included in the second mesh line ML_2 through contact holes. Each of the third connection lines DCL_3 may be electrically connected to all of the third horizontal lines included in the third mesh line ML_3 through contact holes. Each of the fourth connection lines DCL_4 may be electrically connected to all of the fourth horizontal lines included in the fourth mesh line ML_4 through contact holes.

With reference to FIG. 16, because the first to fourth connection lines DCL_1, DCL_2, DCL_3, and DCL_4 are arranged to constitute the plurality of connection line groups DCGa, DCGb, and DCGc, the vertical lines included in each of the first to fourth mesh lines ML_1, ML_2, ML_3, and ML_4 may be arranged to be relatively evenly distributed in the second direction DR2. Accordingly, in each of the first to fourth display areas DA_1 to DA_4, the deviation in the voltage drop of the high power voltage between areas divided along the second direction DR2 may be prevented or reduced, thus the display quality of the display device may be improved.

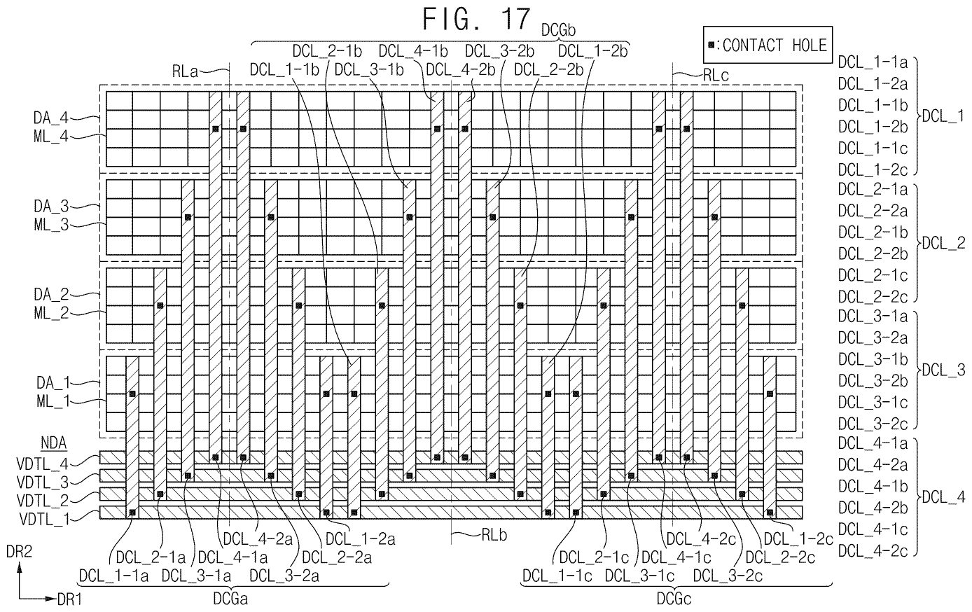

FIG. 17 is a plan view schematically illustrating still another example of a portion of a display panel according to one or more embodiments.

Referring to FIG. 17, in one or more embodiments, when the first to fourth connection lines DCL_1, DCL_2, DCL_3, and DCL_4 are arranged to constitute the plurality of connection line groups DCGa, DCGb, and DCGc, each of the first connection lines DCL_1 may be connected to some of the first horizontal lines HPDL1 included in the first mesh line ML_1 through contact holes, and may not be connected to the remaining first horizontal lines HPDL1. Similarly, each of the second connection lines DCL_2 may be connected to some of the second horizontal lines HPDL2 included in the second mesh line ML_2 through contact holes, and may not be connected to the remaining second horizontal lines HPDL2. Similarly, each of the third connection lines DCL_3 may be connected to some of the third horizontal lines HPDL3 included in the third mesh line ML_3 through contact holes, and may not be connected to the remaining third horizontal lines HPDL3. Similarly, each of the fourth connection lines DCL_4 may be connected to some of the fourth horizontal lines HPDL4 included in the fourth mesh line ML_4 through contact holes, and may not be connected to the remaining fourth horizontal lines HPDL4.

With reference to FIG. 17, in each of the first to fourth display areas DA_1 to DA_4, the deviation in the voltage drop of the high power voltage between areas divided along the second direction DR2 may be prevented or reduced, and also, the deviation in the voltage drop of the high power voltage between an area near the first to fourth high power transmission lines VDTL_1 to VDTL_4 and an area farther away (e.g., areas divided along the first direction DR1) may be prevented or reduced. Thus, the display quality of the display device may be further improved.

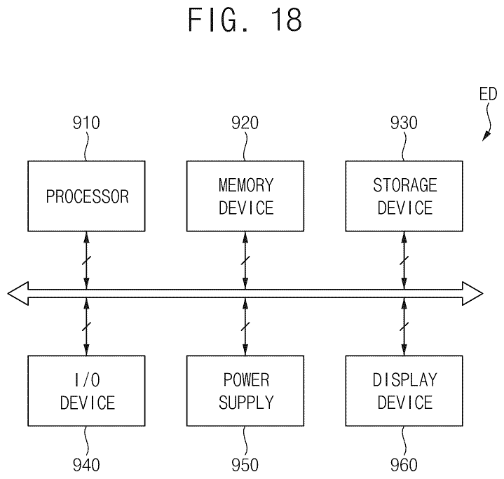

FIG. 18 is a block diagram illustrating an electronic device according to one or more embodiments.

Referring to FIG. 18, in one or more embodiments, the electronic device ED may include a processor 910, a memory device 920, a storage device 930, an input/output (“I/O”) device 940, a power supply 950, and a display device 960. Here, the display device 960 may correspond to the display device DD described above. The electronic device ED may further include a plurality of ports for communicating with a video card, a sound card, a memory card, a universal serial bus (“USB”) device, or the like.

The processor 910 may perform various computing functions or tasks. In one or more embodiments, the processor 910 may be a microprocessor, a central processing unit (“CPU”), an application processor (“AP”), or the like. The processor 910 may be coupled to other components via an address bus, a control bus, a data bus, or the like. In one or more embodiments, the processor 910 may be coupled to an extended bus such as a peripheral component interconnection (“PCI”) bus.

The memory device 920 may store data for operations of the electronic device ED. In one or more embodiments, the memory device 920 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In one or more embodiments, the storage device 930 may include a solid state drive (“SSD”) device, a hard disk drive (“HDD”) device, a CD-ROM device, or the like. In one or more embodiments, the I/O device 940 may include an input device such as a keyboard, a keypad, a mouse device, a touchpad, a touch-screen, or the like, and an output device such as a printer, a speaker, or the like.

The power supply 950 may provide power for operations of the electronic device ED. The display device 960 may be coupled to other components via the buses or other communication links. In one or more embodiments, the display device 960 may be included in the I/O device 940.

Although embodiments and implementations have been described herein, other embodiments and modifications will be apparent from this description. Accordingly, the present disclosure is not limited to such embodiments, but rather to the broader scope of the appended claims and various obvious modifications and equivalent arrangements as would be apparent to a person of ordinary skill in the art.

What is claimed is:

1. A display panel comprising:
a substrate comprising a first display area and a second display area, and a non-display area outside the first and second display areas;
a first mesh line in the first display area, and electrically connected to pixels in the first display area;
a second mesh line in the second display area, and electrically connected to pixels in the second display area;
a first high power transmission line in the non-display area, electrically connected to the first mesh line, and configured to transmit a first high power voltage to the first mesh line; and
a second high power transmission line in the non-display area, electrically connected to the second mesh line, and configured to transmit a second high power voltage to the second mesh line.

2. The display panel of claim 1, wherein the first mesh line and the second mesh line are electrically insulated from each other.

3. The display panel of claim 1, wherein the first high power transmission line and the second high power transmission line are electrically insulated from each other.

4. The display panel of claim 1, wherein the first high power transmission line extends in a first direction, and
wherein the second high power transmission line extends in the first direction, and is spaced apart from the first high power transmission line in a second direction crossing the first direction.

5. The display panel of claim 4, further comprising:
first connection lines extending in the second direction, and connecting the first high power transmission line and the first mesh line; and
second connection lines extending in the second direction, and connecting the second high power transmission line and the second mesh line.

6. The display panel of claim 5, wherein the first display area is in the second direction from the second high power transmission line,
wherein the second display area is in the second direction from the first display area, and
wherein a length of the second connection lines in the second direction is greater than a length of the first connection lines in the second direction.

7. The display panel of claim 6, wherein the first connection lines extend from the first high power transmission line in the second direction, overlap the first display area in a plan view, and are spaced apart from the second display area in the plan view, and
wherein the second connection lines extend from the second high power transmission line in the second direction, and overlap the first display area and the second display area in the plan view.

8. The display panel of claim 5, wherein the second mesh line comprises:
horizontal lines extending in the first direction, and spaced apart from each other in the second direction; and
vertical lines extending in the second direction, spaced apart from each other in the first direction, at a different layer from the horizontal lines, and electrically connected to the horizontal lines through contact holes.

9. The display panel of claim 8, wherein the second connection lines are electrically connected to at least one of the horizontal lines in the second display area through a contact hole.

10. The display panel of claim 9, wherein the second connection lines are electrically connected to some of the horizontal lines in the second display area, which are in a central portion of the second display area in the second direction, through a contact hole.

11. The display panel of claim 8, wherein the vertical lines, the first connection lines, and the second connection lines are at a same layer.

12. The display panel of claim 11, wherein one of the vertical lines in the second display area is aligned with one of the first connection lines in the first display area in the second direction.

13. The display panel of claim 5, wherein the second display area is in the second direction from the first display area,
wherein a virtual reference line extends in the second direction, and passes through a center of the first display area and a center of the second display area, and
wherein the first connection lines comprises:
first-first connection lines; and
first-second connection lines symmetrical with the first-first connection lines with respect to the virtual reference line.

14. The display panel of claim 13, wherein the second connection lines comprise:
second-first connection lines adjacent to the first-first connection lines; and
second-second connection lines symmetrical with the second-first connection lines with respect to the virtual reference line, and adjacent to the first-second connection lines.

15. The display panel of claim 5, wherein the second display area is in the second direction from the first display area,
wherein a first virtual reference line extends in the second direction, and passes through the first display area and the second display area,
wherein a second virtual reference line extends in the second direction, passes through the first display area and the second display area, and is spaced apart from the first virtual reference line in the first direction,
wherein the first connection lines comprise:
a first-first connection line;
a first-second connection line symmetrical with the first-first connection line with respect to the first virtual reference line;
a first-third connection line adjacent to the first-second connection line; and
a first-fourth connection line symmetrical with the first-third connection line with respect to the second virtual reference line.

16. The display panel of claim 15, wherein the second connection lines comprise:
a second-first connection line adjacent to the first-first connection line;
a second-second connection line symmetrical with the second-first connection line with respect to the first virtual reference line, and adjacent to the first-second connection line;
a second-third connection line adjacent to the first-third connection line; and
a second-fourth connection line symmetrical with the second-third connection line with respect to the second virtual reference line, and adjacent to the first-fourth connection line.

17. A display device comprising:
a display panel comprising a first display area and a second display area, and a non-display area outside the first and second display areas; and
a panel driver configured to drive the display panel based on input image data, and to provide high power voltages to the first and second display areas, respectively,
wherein the display panel comprises:
a first mesh line in the first display area, and electrically connected to pixels in the first display area;
a second mesh line in the second display area, and electrically connected to pixels in the second display area;
a first high power transmission line in the non-display area, electrically connected to the first mesh line, and configured to transmit a first high power voltage to the first mesh line; and
a second high power transmission line in the non-display area, electrically connected to the second mesh line, and configured to transmit a second high power voltage to the second mesh line.

18. The display device of claim 17, wherein the panel driver is configured to divide the input image data into region image data for the first and second display areas, and
wherein the panel driver is configured to determine a target voltage level of the high power voltages respectively corresponding the first and second display areas by analyzing a corresponding one of the region image data.

19. The display device of claim 18, wherein the panel driver is configured to calculate an average gray level of gray levels represented by pixel data comprised in the corresponding one of the region image data, and
wherein the panel driver is configured to determine the target voltage level of a corresponding one of the high power voltages based on the average gray level.

20. An electronic device comprising:
a window;
a housing coupled with the window to provide an internal space;
a display panel accommodated in the internal space between the housing and the window, and comprising a first display area and a second display area, and a non-display area outside the first and second display areas; and
a panel driver configured to drive the display panel based on input image data, and to provide high power voltages to the first and second display areas, respectively,
wherein the display panel comprises:
a first mesh line in the first display area, and electrically connected to pixels in the first display area;
a second mesh line in the second display area, and electrically connected to pixels in the second display area;
a first high power transmission line in the non-display area, electrically connected to the first mesh line, and configured to transmit a first high power voltage to the first mesh line; and
a second high power transmission line in the non-display area, electrically connected to the second mesh line, and configured to transmit a second high power voltage to the second mesh line.
